(19) United States
(12) Patent Application Publication
(10) Pub. No.: US 2024/0136161 A1
(43) Pub. Date: Apr. 25, 2024

(54) TRIPOLAR ELECTRODE ARRANGEMENT FOR ELECTROSTATIC CHUCKS

(71) Applicant: LAM RESEARCH CORPORATION, Fremont, CA (US)

(72) Inventors: Karl Frederick LEESER, West Linn, OR (US); Richard BLANK, San Jose, CA (US); Jacob L. HIESTER, Newberg, OR (US)

(21) Appl. No.: 18/278,276

(22) PCT Filed: Mar. 11, 2022
(86) PCT No.: PCT/US2022/019863

§ 371 Date: Aug. 21, 2023

Related U.S. Application Data
(60) Provisional application No. 63/161,647, filed on Mar. 16, 2021.

(51) Int. Cl. H01J 37/32; C23C 16/455; C23C 16/458; C23C 16/50; C23C 16/52; H01L 21/683

(52) U.S. Cl. CPC H01J 37/32715; C23C 16/45565; C23C 16/4583; C23C 16/50; C23C 16/52; H01J 37/3244; H01J 37/32541; H01J 37/32568; H01L 21/6833; H01J 2237/2007; H01J 2237/20207

(57) ABSTRACT

A system comprises a pedestal and a controller. The pedestal is arranged below a showerhead in a processing chamber and includes at least three electrodes to clamp a substrate to the pedestal during processing. The controller is configured to measure a pedestal-to-showerhead gap and at least one of a magnitude and a direction of a relative tilt between the pedestal and the showerhead by sensing impedances between the at least three electrodes and the showerhead.

### CROSS-REFERENCE TO RELATED APPLICATIONS

This application claims the benefit of U.S. Provisional Application No. 63/161,647 filed on Mar. 16, 2021. The entire disclosure of the application referenced above is incorporated herein by reference.

### FIELD

The present disclosure relates generally to semiconductor processing systems and more particularly to a tripolar electrode arrangement for electrostatic chucks.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically includes a plurality of processing chambers (also called process modules) to perform deposition, etching, and other treatments of substrates such as semiconductor wafers. Examples of processes that may be performed on a substrate include, but are not limited to, a plasma enhanced chemical vapor deposition (PECVD) process, a chemically enhanced plasma vapor deposition (CEPVD) process, a sputtering physical vapor deposition (PVD) process, atomic layer deposition (ALD), and plasma enhanced ALD (PEALD). Additional examples of processes that may be performed on a substrate include, but are not limited to, etching (e.g., chemical etching, plasma etching, reactive ion etching, etc.) and cleaning processes.

During processing, a substrate is arranged on a substrate support such as a pedestal, an electrostatic chuck (ESC), and so on in a processing chamber of the substrate processing system. During deposition, gas mixtures including one or more precursors are introduced into the processing chamber, and plasma is struck to activate chemical reactions. During etching, gas mixtures including etch gases are introduced into the processing chamber, and plasma is struck to activate chemical reactions. A computer-controlled robot typically transfers substrates from one processing chamber to another in a sequence in which the substrates are to be processed.

### SUMMARY

A system comprises a pedestal and a controller. The pedestal is arranged below a showerhead in a processing chamber and includes at least three electrodes to clamp a substrate to the pedestal during processing. The controller is configured to measure a pedestal-to-showerhead gap and at least one of a magnitude and a direction of a relative tilt between the pedestal and the showerhead by sensing impedances between the at least three electrodes and the showerhead.

In another feature, the pedestal further comprises a circumferential electrode surrounding the at least three electrodes.

In another feature, the pedestal comprises a dielectric plate, and the at least three electrodes are arranged in the dielectric plate.

In another feature, the dielectric plate is laminated.

In another feature, the dielectric plate is monolithic.

In another feature, the dielectric plate is made of a single crystalline material, a vitreous material, or a polymeric material.

In another feature, the system further comprises a plurality of actuators configured to at least one of move the pedestal and reorient the relative tilt between the pedestal and the showerhead. Each of the plurality of actuators has at least three degrees of freedom.

In another feature, the plurality of actuators is configured to at least one of move the pedestal and reorient the relative tilt between the pedestal and the showerhead by moving the pedestal, moving the showerhead, or influencing a relative positioning of the pedestal and the showerhead.

In another feature, the controller is configured to control the actuators to adjust the pedestal-to-showerhead gap and to adjust the at least one of the magnitude and the direction of the relative tilt.

In another feature, the controller is configured to determine based on the impedances whether the substrate is absent, present but not clamped to the pedestal, or present and clamped to the pedestal.

In another feature, the controller is configured to measure a pedestal-to-substrate gap and at least one of a magnitude and a direction of a relative tilt between the pedestal and the substrate by sensing the impedances between the at least three electrodes and the substrate.

In another feature, the controller is configured to measure pedestal-to-substrate relative eccentricity by sensing the impedances between the at least three electrodes and the substrate.

In other features, the pedestal and the showerhead are arranged along a vertical axis. The at least three electrodes are arranged in the pedestal in one or more planes parallel to a horizontal plane that is perpendicular to the vertical axis.

In other features, the at least three electrodes are pie-shaped, and the system further comprises an annular electrode having a greater radius than the at least three electrodes.

In other features, the annular electrode includes a plurality of spoke-like portions extending radially inwards. Each of the spoke-like portions is arranged between a different pair of electrodes from the at least three electrodes.

In other features, the pedestal and the showerhead are arranged along a vertical axis. The at least three electrodes and the annular electrode are arranged in the pedestal in one or more planes parallel to a horizontal plane that is perpendicular to the vertical axis.

In other features, the at least three electrodes are pie-shaped, and the system further comprises a disc shaped electrode having a smaller radius than the at least three electrodes.

In other features, the pedestal and the showerhead are arranged along a vertical axis. The at least three electrodes are arranged in the pedestal in one or more planes parallel to a horizontal plane that is perpendicular to the vertical axis. The disc shaped electrode is arranged in the pedestal in a separate plate parallel to the horizontal plane.

In other features, the at least three electrodes are pie-shaped, and the system further comprises a plurality of arc-shaped electrodes having a radius greater than the at least three electrodes and arranged around the at least three electrodes.

In another feature, the at least three electrodes and the plurality of arc-shaped electrodes are arranged in the pedestal in one or more planes parallel to a horizontal plane.

In other features, the further comprises a plurality of switches, and the controller is configured to connect to the at least three electrodes in pairs using the plurality of switches.

In another feature, the controller comprises a plurality of sensing circuits connected directly to respective pairs of the at least three electrodes to sense impedances.

In other features, the system further comprises a plurality of switches, and the controller is configured to connect to the at least three electrodes and the annular electrode in pairs using the plurality of switches, with each of the pairs including the annular electrode and a different one of the at least three electrodes.

In other features, the system further comprises a plurality of switches, and the controller is configured to connect to the at least three electrodes and the disc shaped electrode in pairs using the plurality of switches, with each of the pairs including the disc shaped electrode and a different one of the at least three electrodes.

In other features, the system further comprises a plurality of switches, and the controller is configured to connect to the at least three electrodes and the plurality of arc-shaped electrodes in pairs using the plurality of switches, with each of the pairs including a different one of the at least three electrodes and a different one of the plurality of arc-shaped electrodes.

In other features, the pedestal comprises a baseplate and a dielectric plate arranged on the baseplate. The at least three electrodes are arranged in the dielectric plate.

In another feature, the at least three electrodes are connected to a single DC potential.

In other features, the at least three electrodes are connected to a first DC potential having a first polarity, and the circumferential electrode is connected to a second DC potential having a second polarity that is opposite to the first polarity.

In other features, the at least three electrodes are connected to a first DC potential having a first polarity, and the disc shaped electrode is connected to a second DC potential having a second polarity that is opposite to the first polarity.

In other features, the at least three electrodes are connected to a first DC potential having a first polarity, and the plurality of arc-shaped electrodes is connected to a second DC potential having a second polarity that is opposite to the first polarity.

In other features, the disc shaped electrode is connected to a first potential, and the at least three electrodes are connected to a time-varying potential with a phase shift of 360 degrees divided a total number of the at least three electrodes.

In other features, the at least three electrodes include a first pair of electrodes and a second pair of electrodes. The first pair of electrodes arranged diametrically opposite to each other and connected to a first DC potential having a first polarity. The second pair of electrodes arranged diametrically opposite to each other and connected to a second DC potential having a second polarity that is opposite to the first polarity.

In other features, the at least three electrodes include a first pair of electrodes and a second pair of electrodes. The first pair of electrodes includes a first electrode and a second electrode that are arranged diametrically opposite to each other and that are respectively connected to first time-varying potentials having a first polarity and a second polarity that is opposite to the first polarity. The second pair of electrodes includes a third electrode and a fourth electrode that are arranged diametrically opposite to each other and that are respectively connected to second time-varying potentials having the first polarity and the second polarity. The second time-varying potentials have a phase shift of 360 degrees divided a total number of the at least three electrodes.

In another feature, the controller is configured to measure the pedestal-to-showerhead gap and at least one of the magnitude and the direction of the relative tilt between the pedestal and the showerhead by sensing impedances between the at least three electrodes and the showerhead with plasma present between the pedestal and the showerhead.

In still other features, a system comprises a pedestal and a controller. The pedestal is arranged below a showerhead in a processing chamber. The pedestal includes at least three electrodes to clamp a substrate to the pedestal during processing. The at least three electrodes are pie-shaped. The pedestal includes an annular electrode having a greater radius than the at least three electrodes. The controller is configured to measure a pedestal-to-showerhead gap and at least one of a magnitude and a direction of a relative tilt between the pedestal and the showerhead by sensing impedances between the showerhead and the at least three electrodes and the annular electrode.

In other features, the annular electrode includes a plurality of spoke-like portions extending radially inwards. Each of the spoke-like portions is arranged between a different pair of electrodes from the at least three electrodes.

In other features, the pedestal and the showerhead are arranged along a vertical axis. The at least three electrodes and the annular electrode are arranged in the pedestal in one or more planes parallel to a horizontal plane that is perpendicular to the vertical axis.

In other features, the system further comprises a plurality of switches. The controller is configured to connect to the at least three electrodes and the annular electrode in pairs using the plurality of switches, with each of the pairs including the annular electrode and a different one of the at least three electrodes.

In other features, the system further comprises a plurality of actuators configured to at least one of move the pedestal and reorient the relative tilt between the pedestal and the showerhead. Each of the plurality of actuators has at least three degrees of freedom.

In other features, the plurality of actuators is configured to at least one of move the pedestal and reorient the relative tilt between the pedestal and the showerhead by moving the pedestal, moving the showerhead, or influencing a relative positioning of the pedestal and the showerhead.

In another feature, the controller is configured to control the actuators to adjust the pedestal-to-showerhead gap and to adjust the at least one of the magnitude and the direction of the relative tilt.

In another feature, the controller is configured to determine based on the impedances whether the substrate is absent, present but not clamped to the pedestal, or present and clamped to the pedestal.

In another feature, the controller is configured to measure a pedestal-to-substrate gap and at least one of a magnitude and a direction of a relative tilt between the pedestal and the substrate by sensing the impedances between the substrate and the at least three electrodes and the annular electrode.

In another feature, the controller is configured to measure pedestal-to-substrate relative eccentricity by sensing the impedances between the substrate and the at least three electrodes and the annular electrode.

In another feature, the controller comprises a plurality of sensing circuits connected directly to respective pairs of the at least three electrodes and the annular electrode to sense impedances.

In other features, the pedestal comprises a baseplate and a dielectric plate arranged on the baseplate. The at least three electrodes and the annular electrode are arranged in the dielectric plate.

In another feature, the at least three electrodes and the annular electrode are connected to a single DC potential.

In another feature, the at least three electrodes are connected to a first DC potential having a first polarity, and the annular electrode is connected to a second DC potential having a second polarity that is opposite to the first polarity.

In another feature, the at least three electrodes include a first pair of electrodes and a second pair of electrodes. The first pair of electrodes is arranged diametrically opposite to each other and connected to a first DC potential having a first polarity. The second pair of electrodes is arranged diametrically opposite to each other and connected to a second DC potential having a second polarity that is opposite to the first polarity.

In another feature, the at least three electrodes include a first pair of electrodes and a second pair of electrodes. The first pair of electrodes includes a first electrode and a second electrode that are arranged diametrically opposite to each other and that are respectively connected to first time-varying potentials having a first polarity and a second polarity that is opposite to the first polarity. The second pair of electrodes includes a third electrode and a fourth electrode that are arranged diametrically opposite to each other and that are respectively connected to second time-varying potentials having the first polarity and the second polarity. The second time-varying potentials have a phase shift of 360 degrees divided a total number of the at least three electrodes.

In another feature, the controller is configured to measure the pedestal-to-showerhead gap and at least one of the magnitude and the direction of the relative tilt between the pedestal and the showerhead by sensing impedances between the showerhead and the at least three electrodes and the annular electrode with plasma present between the pedestal and the showerhead.

In still other features, a system comprises a pedestal and a controller. The pedestal is arranged below a showerhead in a processing chamber. The pedestal includes at least three electrodes to clamp a substrate to the pedestal during processing. The at least three electrodes are pie-shaped. The pedestal includes a disc shaped electrode having a smaller radius than the at least three electrodes. The controller is configured to measure a pedestal-to-showerhead gap and at least one of a magnitude and a direction of a relative tilt between the pedestal and the showerhead by sensing impedances between the showerhead and the at least three electrodes and the disc shaped electrode.

In other features, the pedestal and the showerhead are arranged along a vertical axis. The at least three electrodes are arranged in the pedestal in one or more planes parallel to a horizontal plane that is perpendicular to the vertical axis, and the disc shaped electrode is arranged in the pedestal in a separate plate parallel to the horizontal plane.

In other features, the system further comprises a plurality of switches. The controller is configured to connect to the at least three electrodes and the disc shaped electrode in pairs using the plurality of switches, with each of the pairs including the disc shaped electrode and a different one of the at least three electrodes.

In other features, the at least three electrodes are connected to a first DC potential having a first polarity. The disc shaped electrode is connected to a second DC potential having a second polarity that is opposite to the first polarity.

In other features, the system further comprises a plurality of actuators configured to at least one of move the pedestal and reorient the relative tilt between the pedestal and the showerhead. Each of the plurality of actuators has at least three degrees of freedom.

In other features, the plurality of actuators is configured to at least one of move the pedestal and reorient the relative tilt between the pedestal and the showerhead by moving the pedestal, moving the showerhead, or influencing a relative positioning of the pedestal and the showerhead.

In another feature, the controller is configured to control the actuators to adjust the pedestal-to-showerhead gap and to adjust the at least one of the magnitude and the direction of the relative tilt.

In another feature, the controller is configured to determine based on the impedances whether the substrate is absent, present but not clamped to the pedestal, or present and clamped to the pedestal.

In another feature, the controller is configured to measure a pedestal-to-substrate gap and at least one of a magnitude and a direction of a relative tilt between the pedestal and the substrate by sensing the impedances between the substrate and the at least three electrodes and the disc shaped electrode.

In another feature, the controller is configured to measure pedestal-to-substrate relative eccentricity by sensing the impedances between the substrate and the at least three electrodes and the disc shaped electrode.

In another feature, the controller comprises a plurality of sensing circuits connected directly to respective pairs of the at least three electrodes and the disc shaped electrode to sense impedances.

In other features, the pedestal comprises a baseplate and a dielectric plate arranged on the baseplate. The at least three electrodes and the disc shaped electrode are arranged in the dielectric plate.

In another feature, the at least three electrodes and the disc shaped electrode are connected to a single DC potential.

In another feature, the at least three electrodes include a first pair of electrodes and a second pair of electrodes. The first pair of electrodes is arranged diametrically opposite to each other and connected to a first DC potential having a first polarity. The second pair of electrodes is arranged diametrically opposite to each other and connected to a second DC potential having a second polarity that is opposite to the first polarity.

In another feature, the at least three electrodes include a first pair of electrodes and a second pair of electrodes. The first pair of electrodes includes a first electrode and a second electrode that are arranged diametrically opposite to each other and that are respectively connected to first time-varying potentials having a first polarity and a second polarity that is opposite to the first polarity. The second pair of electrodes includes a third electrode and a fourth electrode that are arranged diametrically opposite to each other and that are respectively connected to second time-varying potentials having the first polarity and the second polarity. The second time-varying potentials have a phase shift of 360 degrees divided a total number of the at least three electrodes.

In another feature, the controller is configured to measure the pedestal-to-showerhead gap and at least one of the magnitude and the direction of the relative tilt between the pedestal and the showerhead by sensing impedances between the showerhead and the at least three electrodes and the disc shaped electrode with plasma present between the pedestal and the showerhead.

In still other features, a system comprises a pedestal and a controller. The pedestal is arranged below a showerhead in a processing chamber. The pedestal includes at least three electrodes to clamp a substrate to the pedestal during processing. The at least three electrodes are pie-shaped. The pedestal includes a plurality of arc-shaped electrodes having a radius greater than the at least three electrodes and arranged around the at least three electrodes. The controller is configured to measure a pedestal-to-showerhead gap and at least one of a magnitude and a direction of a relative tilt between the pedestal and the showerhead by sensing impedances between the showerhead and the at least three electrodes and the plurality of arc-shaped electrodes.

In other features, the pedestal and the showerhead are arranged along a vertical axis. The at least three electrodes and the plurality of arc-shaped electrodes are arranged in the pedestal in one or more planes parallel to a horizontal plane that is perpendicular to the vertical axis.

In other features, the system further comprises a plurality of switches. The controller is configured to connect to the at least three electrodes and the plurality of arc-shaped electrodes in pairs using the plurality of switches, with each of the pairs including a different one of the at least three electrodes and a different one of the plurality of arc-shaped electrodes.

In other features, the at least three electrodes are connected to a first DC potential having a first polarity. The plurality of arc-shaped electrodes is connected to a second DC potential having a second polarity that is opposite to the first polarity.

In other features, the system further comprises a plurality of actuators configured to at least one of move the pedestal and reorient the relative tilt between the pedestal and the showerhead. Each of the plurality of actuators has at least three degrees of freedom.

In other features, the plurality of actuators is configured to at least one of move the pedestal and reorient the relative tilt between the pedestal and the showerhead by moving the pedestal, moving the showerhead, or influencing a relative positioning of the pedestal and the showerhead.

In another feature, the controller is configured to control the actuators to adjust the pedestal-to-showerhead gap and to adjust the at least one of the magnitude and the direction of the relative tilt.

In another feature, the controller is configured to determine based on the impedances whether the substrate is absent, present but not clamped to the pedestal, or present and clamped to the pedestal.

In another feature, the controller is configured to measure a pedestal-to-substrate gap and at least one of a magnitude and a direction of a relative tilt between the pedestal and the substrate by sensing the impedances between the substrate and the at least three electrodes and the plurality of arc-shaped electrodes.

In another feature, the controller is configured to measure pedestal-to-substrate relative eccentricity by sensing the impedances between the substrate and the at least three electrodes and the plurality of arc-shaped electrodes.

In another feature, the controller comprises a plurality of sensing circuits connected directly to respective pairs of the at least three electrodes and the plurality of arc-shaped electrodes to sense impedances.

In another feature, the pedestal comprises a baseplate and a dielectric plate arranged on the baseplate. The at least three electrodes and the plurality of arc-shaped electrodes are arranged in the dielectric plate.

In another feature, the at least three electrodes and the plurality of arc-shaped electrodes are connected to a single DC potential.

In other features, the at least three electrodes include a first pair of electrodes and a second pair of electrodes. The first pair of electrodes is arranged diametrically opposite to each other and connected to a first DC potential having a first polarity. The second pair of electrodes is arranged diametrically opposite to each other and connected to a second DC potential having a second polarity that is opposite to the first polarity.

In other features, the at least three electrodes include a first pair of electrodes and a second pair of electrodes. The first pair of electrodes includes a first electrode and a second electrode that are arranged diametrically opposite to each other and that are respectively connected to first time-varying potentials having a first polarity and a second polarity that is opposite to the first polarity. The second pair of electrodes includes a third electrode and a fourth electrode that are arranged diametrically opposite to each other and that are respectively connected to second time-varying potentials having the first polarity and the second polarity. The second time-varying potentials have a phase shift of 360 degrees divided a total number of the at least three electrodes.

In another feature, the controller is configured to measure the pedestal-to-showerhead gap and at least one of the magnitude and the direction of the relative tilt between the pedestal and the showerhead by sensing impedances between the showerhead and the at least three electrodes and the plurality of arc-shaped electrodes with plasma present between the pedestal and the showerhead.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system comprising a processing chamber including an electrostatic chuck (ESC) and a showerhead;

FIGS. 2A-2F show various arrangements of electrodes that can be used in the ESC to measure a gap and a relative tilt between the ESC and the showerhead;

FIG. 3A shows an example of implementing connections of electrodes and other electrical elements in the ESC to control circuits;

FIGS. 3B and 3C show an example of a biasing system for biasing three clamping electrodes and an RF electrode in the ESC;

FIG. 3D shows an example of a biasing system for biasing four clamping electrodes and an RF electrode in the ESC;

FIGS. 4A-4D show examples of sensing systems that sense substrate states by utilizing different arrangements of electrodes in the ESC;

FIGS. 5A-5D show examples of systems that utilize the sensing systems of FIGS. 4A-4D for measuring the gap and relative tilt between the ESC and the showerhead;

FIGS. 6A and 6B show examples of mechanisms used for adjusting the gap and relative tilt between the ESC and the showerhead;

FIG. 7 shows a method for measuring and adjusting the gap and relative tilt between the ESC and the showerhead.

FIG. 8A shows a method for detecting whether a substrate is misplaced (i.e., placed off-center) on the ESC;

FIG. 8B shows a method for detecting whether a substrate moves off-center on the ESC during processing;

FIG. 9 shows a method for measuring a gap and relative tilt between the ESC and the substrate;

FIG. 10 shows an example of lift pins used with the ESC; and

FIGS. 11A and 11B are timing diagrams of potentials applied to electrodes shown in FIGS. 2C and 2F in examples of clamping schemes employed using the biasing systems shown in FIGS. 3B-3D.

In the drawings, reference numbers may be reused to identify similar and/or identical elements.

### DETAILED DESCRIPTION

In process modules, pedestal-to-showerhead gap and tilt control is critical for modern semiconductor wafer processing. Particularly, processes performed at relatively high temperatures (>400° C.) tend to be more sensitive to gap and tilt control than others, and more processes are moving into the high-temperature space. While pedestal-to-showerhead gap and tilt can be measured at room temperature, the measurements in high-temperature processes can be challenging since key components of the process modules expand and move when heated to actual processes temperatures. Measurement systems in such environments are typically indirect and often require use of actual substrates to perform gap and tilt tuning. Using actual substrates consumes customers' silicon and wastes substrates. In-situ direct measurement systems that can operate at these high temperatures (>400° C.) temperatures are therefore desired. Also, deposition can build up on traditional optical sensor windows making them unusable for such measurements over time. Further, implementing a line-of-sight sensor between the pedestal and the showerhead can create process performance issues (i.e., adding holes in showerhead affects uniformity). According to the present disclosure, electrodes in electrostatic chucks (ESCs) can be employed to measure gap and tilt as described below.

ESCs typically include a bipolar pair of inner electrodes of opposite polarity and an outer electrode that can be RF or DC biased independently. A sensing circuit can measure impedance between the pair of inner electrodes to assess substrate states: no wafer, wafer present, and wafer clamped. The present disclosure provides a system comprising a tripolar electrode arrangement in an ESC that is used for substrate and ESC-to-showerhead gap sensing with spatial resolution enabling tilt calculations. Briefly, the system comprises two elements: a) a mechanism for moving the ESC to within approximately one millimeter (1 mm) of the showerhead and measuring the ESC-to-showerhead gap by utilizing a sensing circuit that is used to sense substrate states; and b) an additional third inner electrode to enable the measurement and adjustment of ESC-to-showerhead relative tilt.

From the measurement in a), precision position information from a pedestal Z-drive assembly (i.e., a drive assembly with a drive axis orthogonal to the electrode plane to move the pedestal vertically relative to the showerhead) can be added to a measured displacement of the ESC to calculate a net ESC-to-showerhead distance (i.e., the ESC-to-showerhead gap). Denoting the three electrodes as A, B, and C, the third electrode allows the following modes of differential impedance measurements using the sensing circuit: 1) A to B, B to C, and C to A; and 2) A to outer electrode, B to outer electrode, and C to outer electrode, as described below in detail. From these measurements, a local displacement of the ESC relative to the showerhead can be inferred. From the three sets of local displacement measurements, a relative tilt can be calculated. The tilt measurement can then be used to adjust the ESC-to-showerhead relative tilt to tune on-substrate performance. These and other features of the present disclosure are described below in detail.

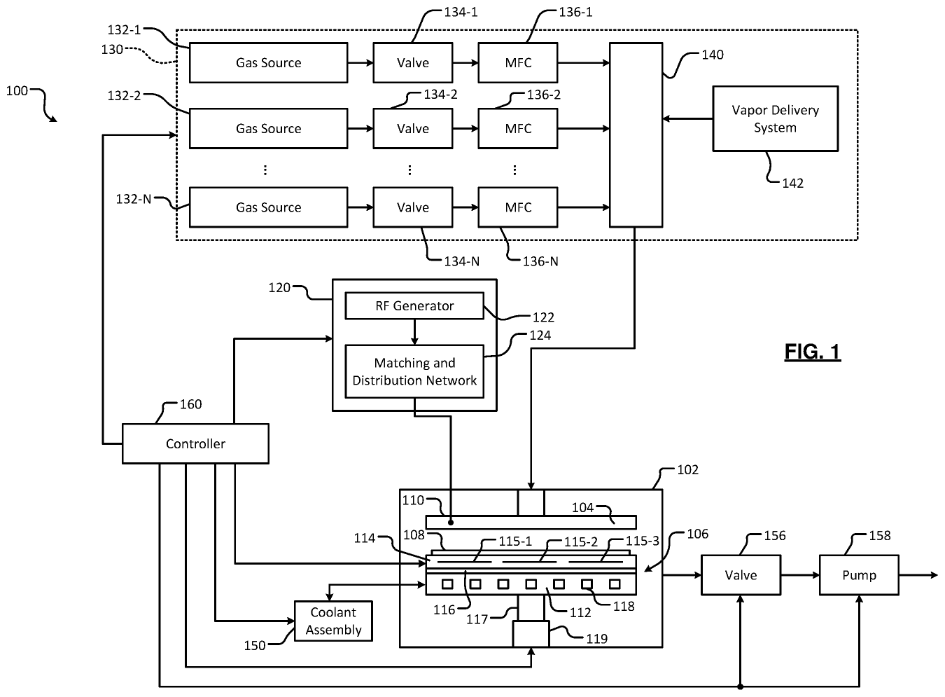

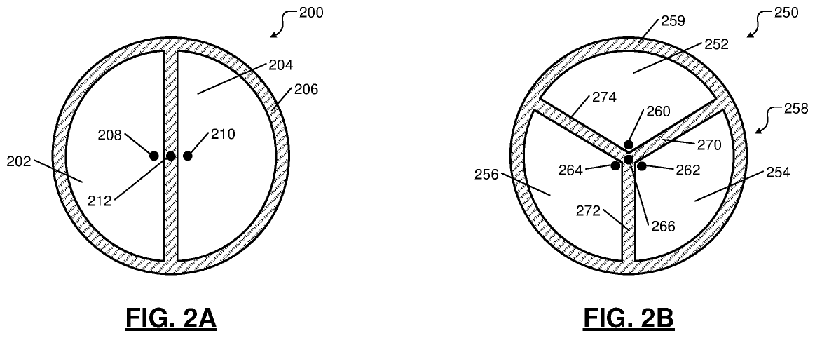

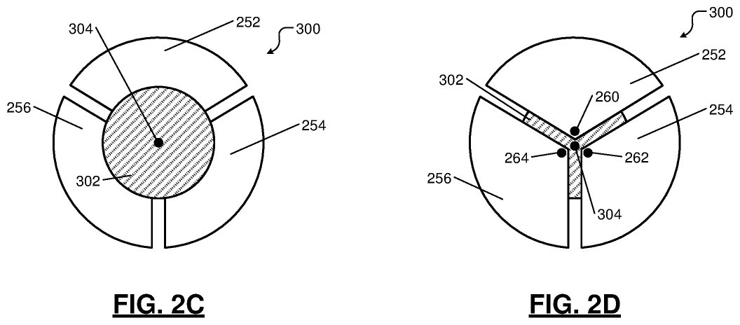

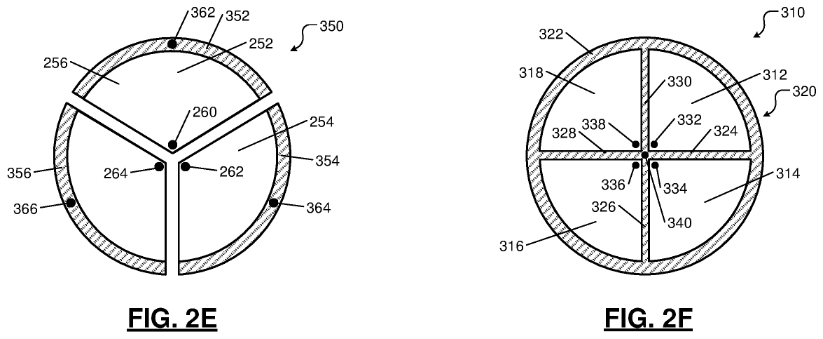

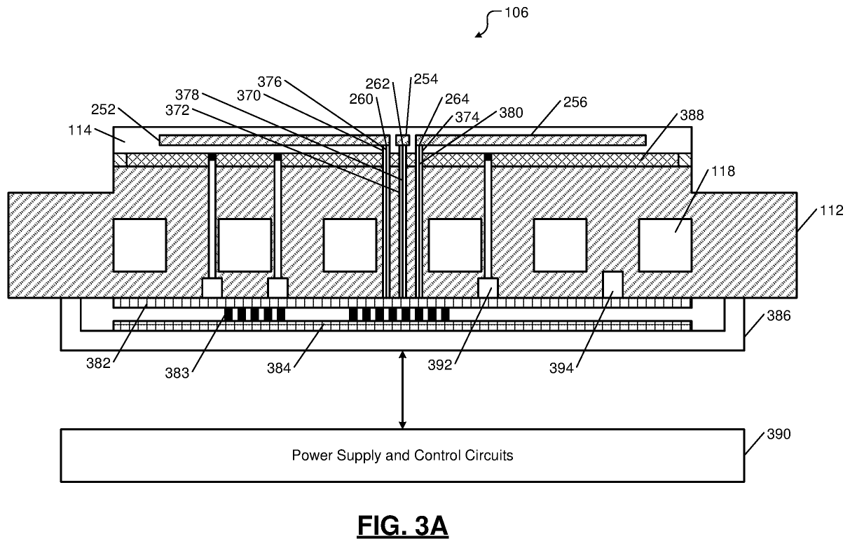

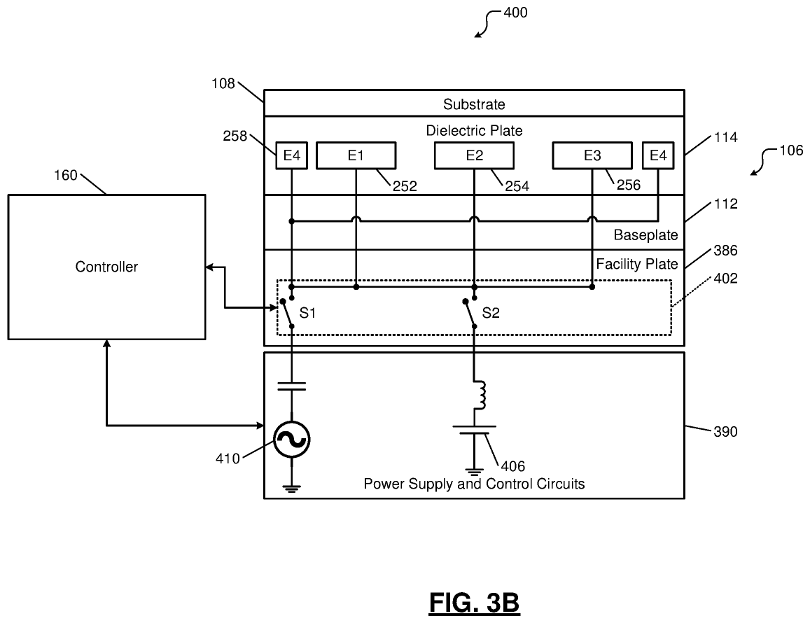

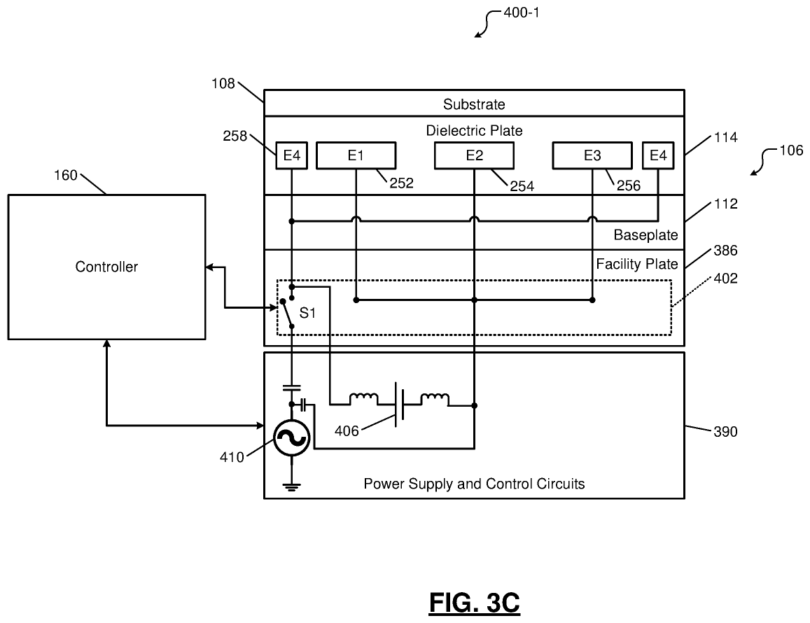

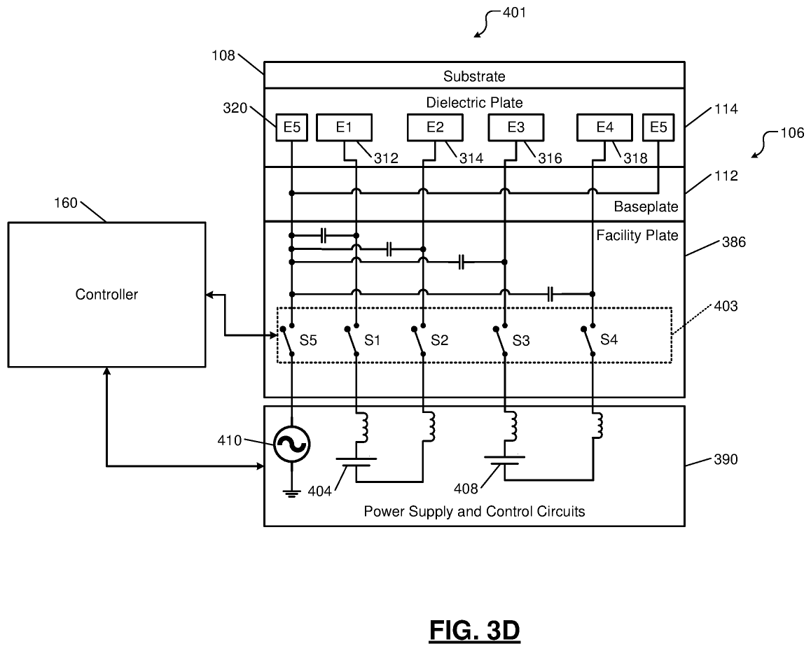

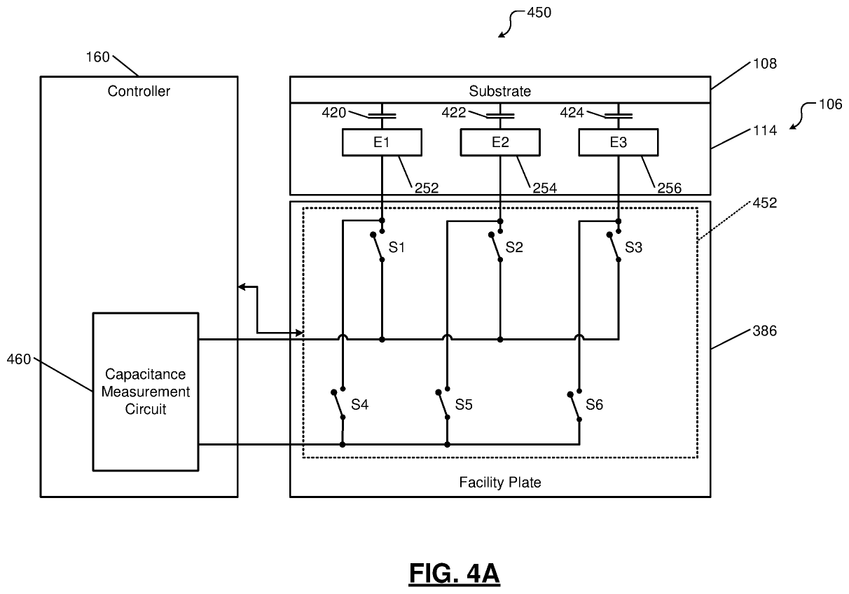

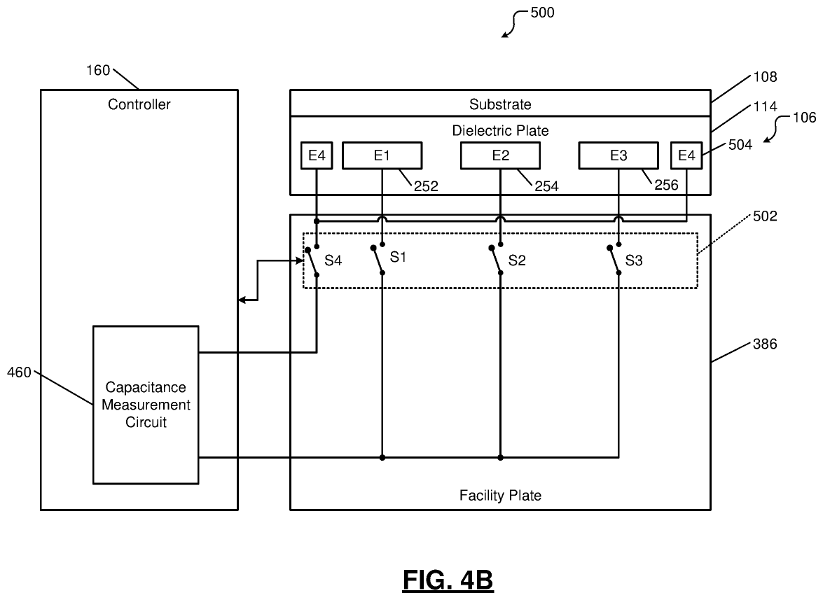

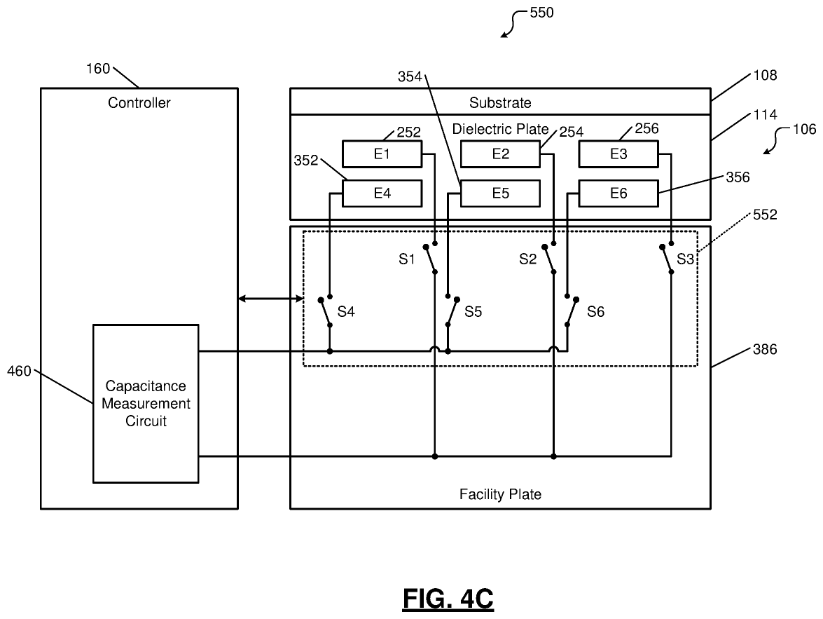

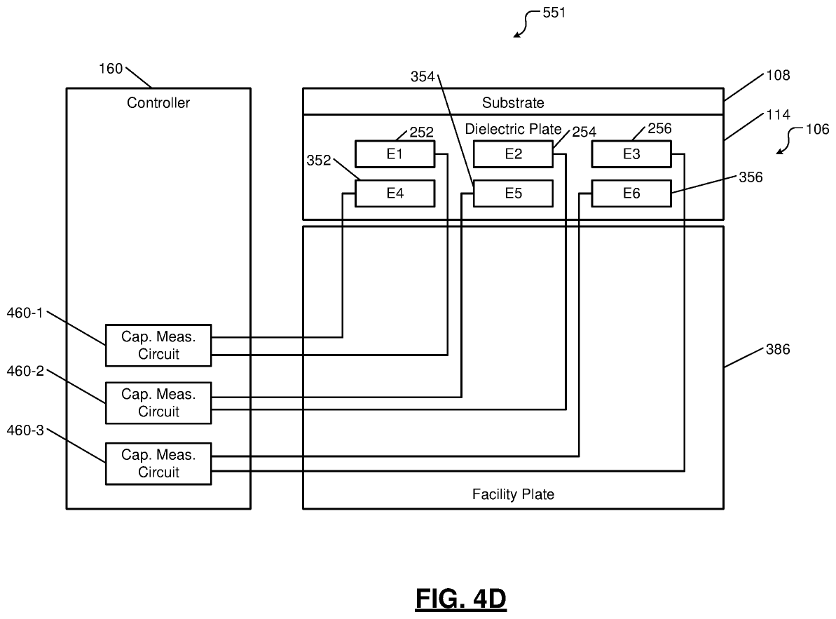

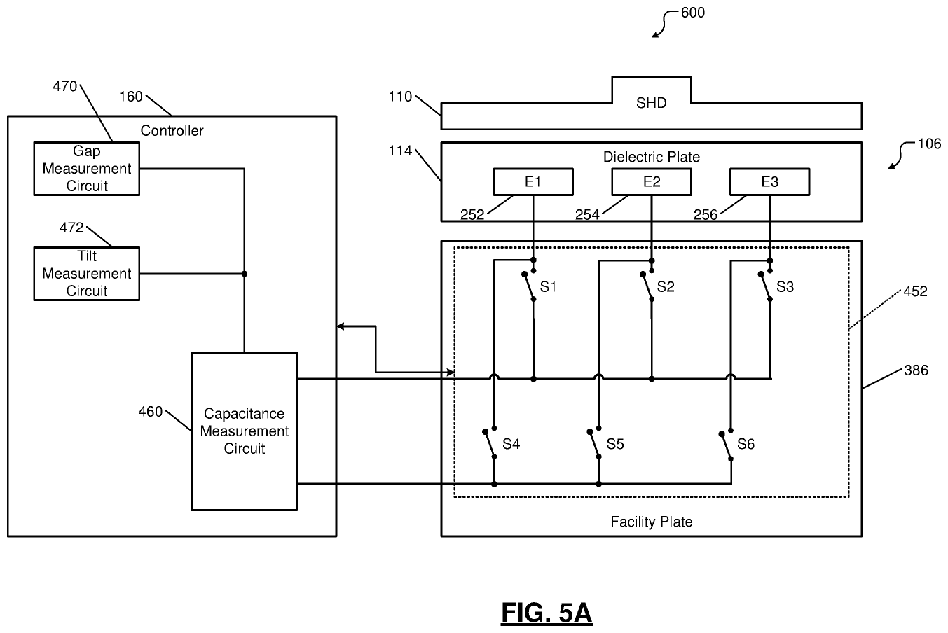

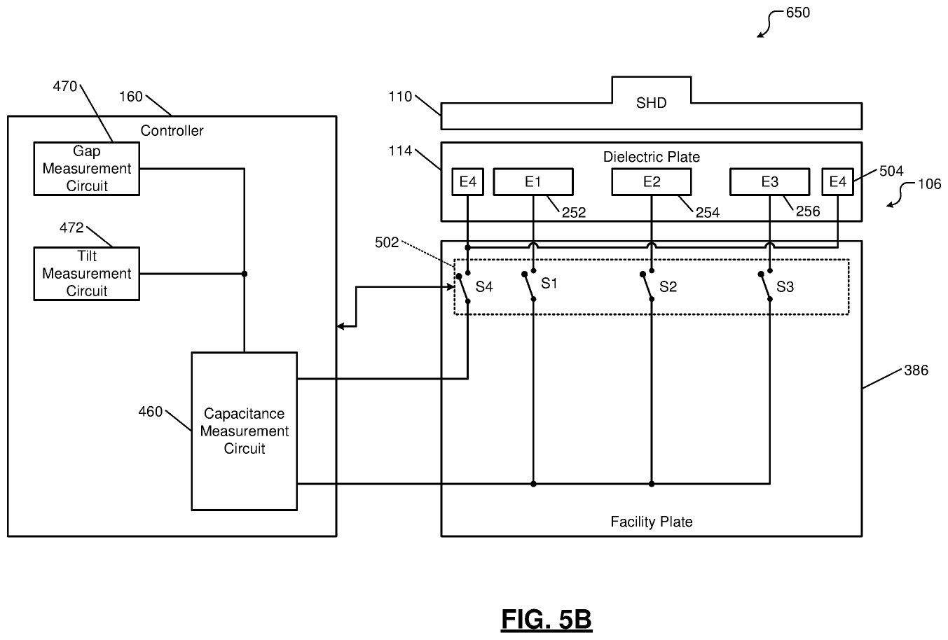

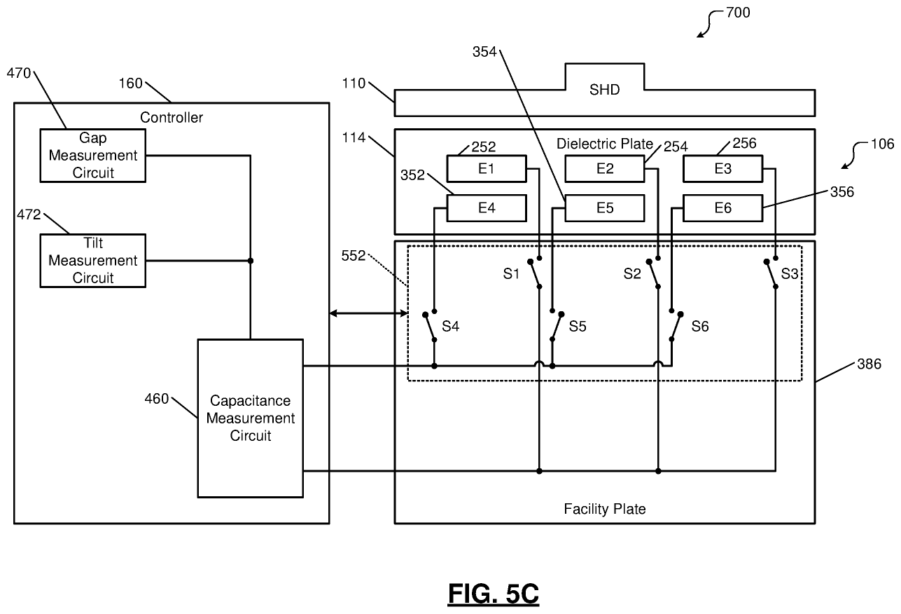

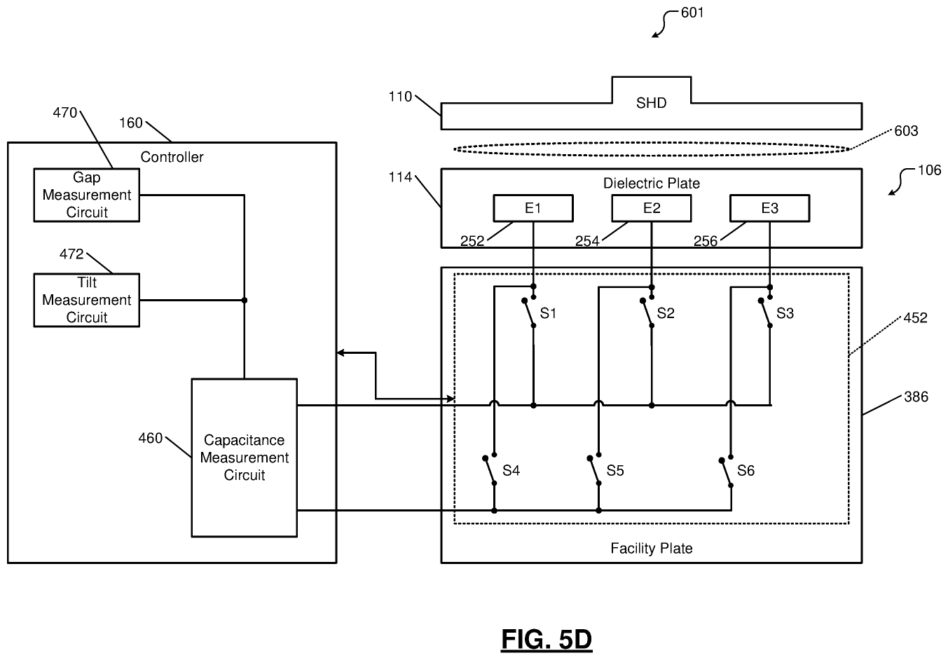

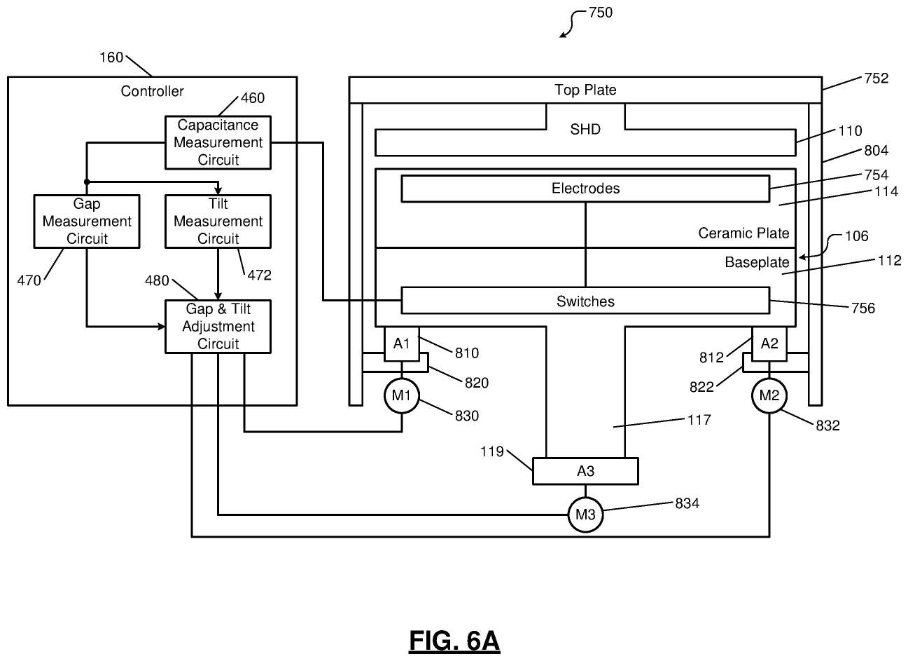

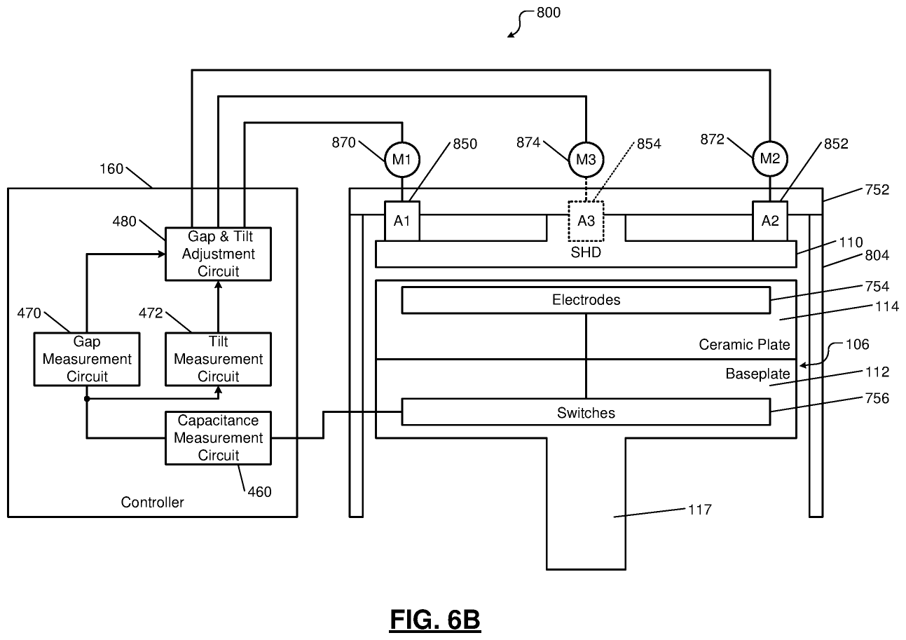

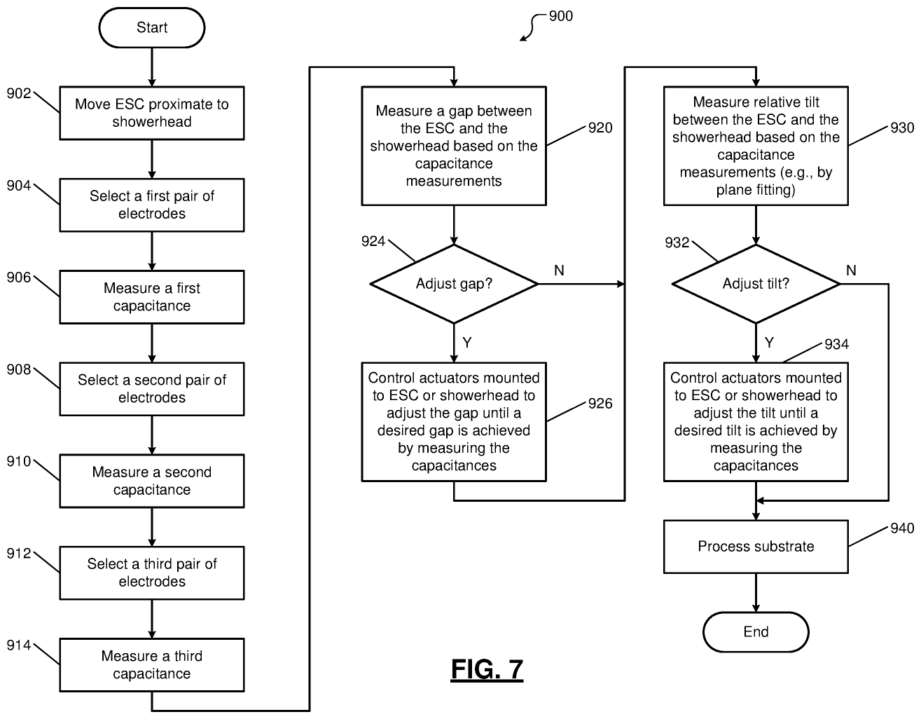

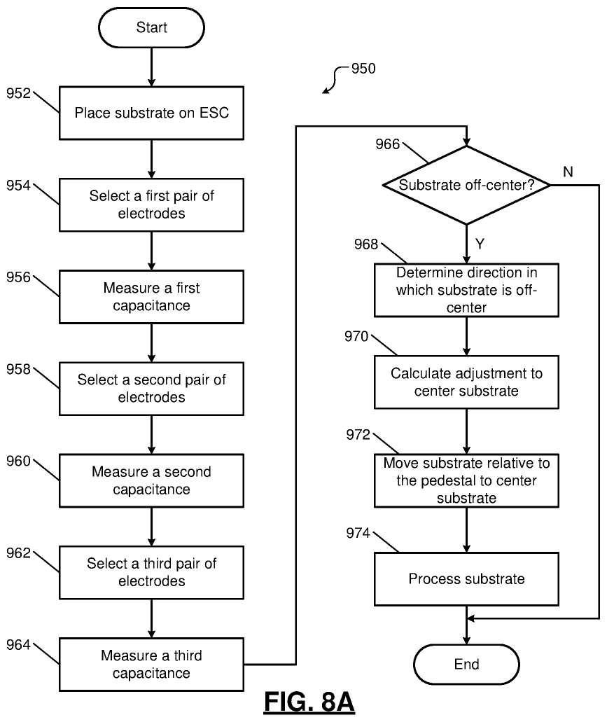

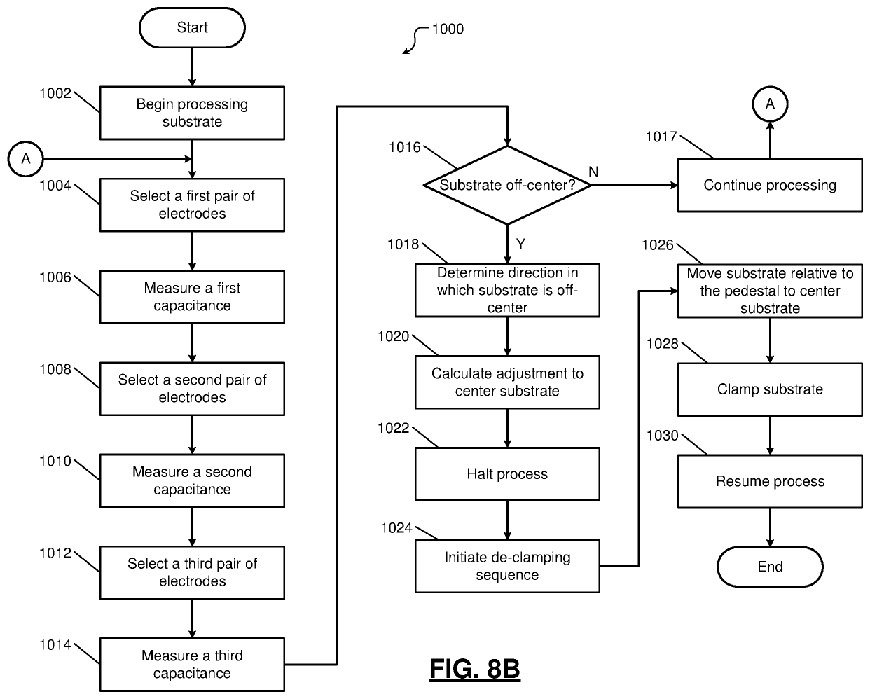

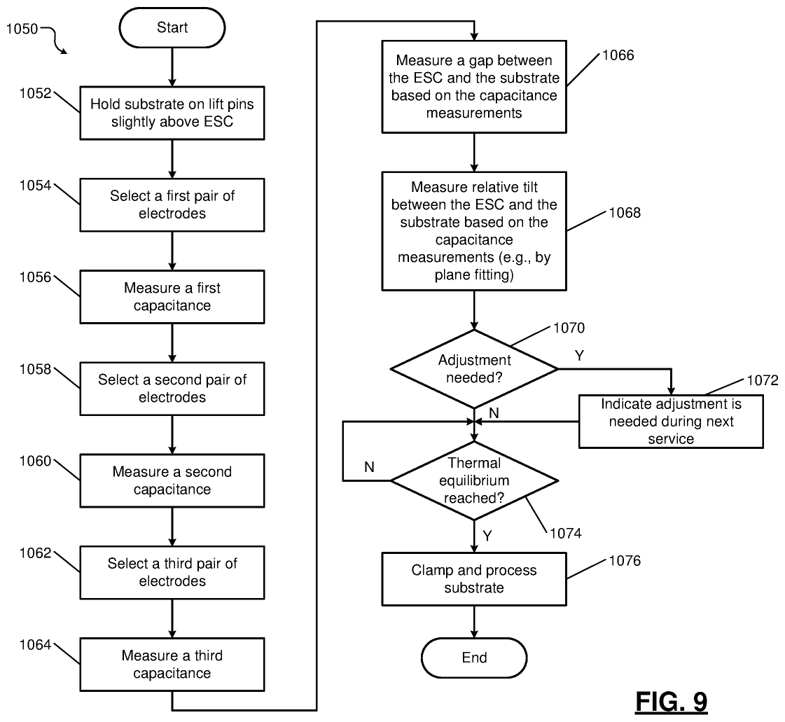

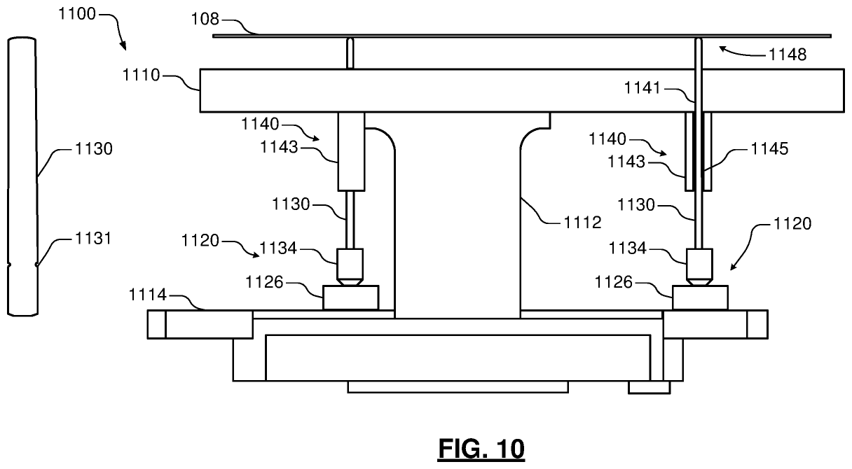

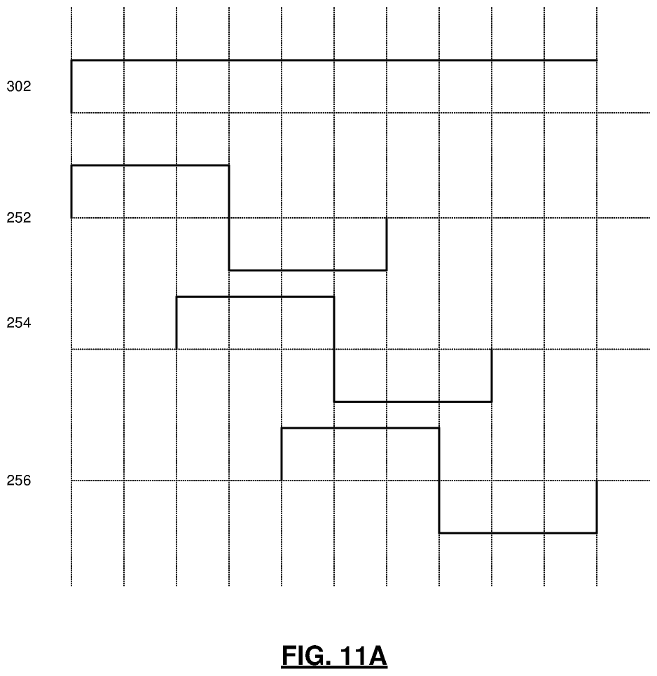

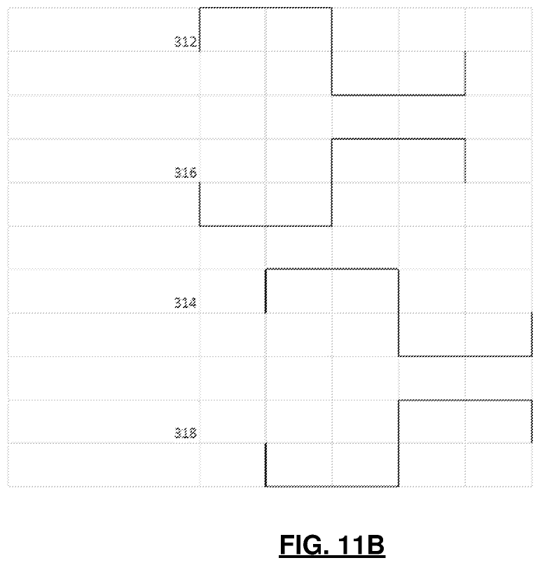

The present disclosure is organized as follows. Initially, an example of a substrate processing system in which a gap and tilt measuring system of the present disclosure can be implemented is shown and described with reference to FIG. 1. Subsequently, various arrangements of electrodes that can be utilized in the gap and tilt measuring system are shown and described with reference to FIGS. 2A-2F. An example of implementing connections of electrodes and other electrical elements in the ESC to control circuits is shown and described with reference to FIG. 3A. Examples of a biasing system to bias three clamping electrodes and an RF electrode in an ESC are shown and described with reference to FIGS. 3B and 3C. An example of a biasing system to bias four clamping electrodes and an RF electrode in an ESC is shown and described with reference to FIG. 3D. Examples of sensing systems that sense substrate states by utilizing different arrangements of electrodes in the ESC are shown and described with reference to FIGS. 4A-4D. Examples of systems that utilize these sensing systems for measuring the gap and relative tilt between the ESC and the showerhead are shown and described with reference to FIGS. 5A-5D. Examples of mechanisms that can be used for adjusting the gap and relative tilt between the ESC and the showerhead are shown and described with reference to FIGS. 6A and 6B. A method for measuring and adjusting the gap and relative tilt between the ESC and the showerhead is shown and described with reference to FIG. 7. A method for detecting whether a substrate is misplaced (i.e., placed off-center) on the ESC is shown and described with reference to FIG. 8A. A method for detecting whether a substrate moves off-center on the ESC during processing is shown and described with reference to FIG. 8B. A method for measuring a gap and relative tilt between the ESC and the substrate is shown and described with reference to FIG. 9. An example of lift pins used with the ESC is shown and described with reference to FIG. 10. Examples of clamping schemes that can be employed using the electrode arrangements shown in FIGS. 2B-2F and using the biasing systems shown in FIGS. 3B and 3C are shown and described with reference to FIGS. 11A and 11B.

Throughout the present disclosure, while the term pedestal is used, the pedestal includes a substrate support also called a susceptor, an electrostatic chuck (ESC), and so on. Further, while the term capacitance is used, the term impedance, which includes capacitance, may be generally used instead. The pedestal-to-showerhead gap is a distance—a measure of physical displacement—between the pedestal and the showerhead.

FIG. 1 shows an example of a substrate processing system 100 comprising a processing chamber 102. While the example is described in the context of plasma enhanced chemical vapor deposition (PECVD), the teachings of the present disclosure can be applied to other types of substrate processing such as atomic layer deposition (ALD), plasma enhanced ALD (PEALD), CVD, or other types of processing including etching. The substrate processing system 100 comprises the processing chamber 102 that encloses other components of the substrate processing system 100 and that contains an RF plasma (if used).

The processing chamber 102 comprises an upper electrode 104 and an electrostatic chuck (ESC) 106 on which a substrate 108 is arranged during processing. For example, the upper electrode 104 may include a gas distribution device 110 such as a showerhead that introduces and distributes process gases into the processing chamber 102. The showerhead 110 may include a stem portion including one end connected to a top surface of the processing chamber 102. A base portion of the showerhead 110 is generally cylindrical and extends radially outwardly from an opposite end of the stem portion at a location that is spaced from the top surface of the processing chamber 102. A substrate-facing surface or faceplate of the base portion of the showerhead 110 includes a plurality of holes through which vaporized precursor, process gas, or purge gas flows. Alternately, the upper electrode 104 may include a conducting plate, and the process gases may be introduced in another manner.

The ESC 106 comprises a baseplate 112 made of a metal (e.g., aluminum) that acts as a lower electrode. The baseplate 112 supports a dielectric plate 114 that may include one or more heaters such as zone heaters (not shown). A thermal resistance layer 116 may be arranged between the dielectric plate 114 and the baseplate 112. The baseplate 112 may also include one or more channels 118 for flowing coolant through the baseplate 112. The ESC 106 includes a stem portion 117 that extends vertically downwards from the center of the baseplate 112 and that supports the baseplate 112. An actuator 119 is coupled to the stem portion 117 and is controlled by a controller 160 to move the ESC 106 relative to the showerhead 110.

The dielectric plate 114 may be monolithic or a laminated assembly. The dielectric plate 114 may also be made from single crystalline material such as sapphire, vitreous material such as various glasses, or polymeric material. The dielectric plate 114 includes at least three clamping electrodes 115-1, 115-2, 115-3 (collectively the clamping electrodes 115). The clamping electrodes 115 are used for clamping the substrate 108 to the dielectric plate 114 during processing. Various examples and arrangements of the clamping electrodes 115 are shown and described below in detail with references to FIGS. 2A-2E. The clamping electrodes 115 are generally shown connected to the controller 160. While FIG. 1 shows the connections generally, examples of detailed connections are shown in FIGS. 3A-4D. An example of a clamping system is shown and described with reference to FIG. 3B. Additionally, the clamping electrodes 115 are used for sensing a gap between the ESC 106 and the showerhead 110 and for measuring relative tilt between the ESC 106 and the showerhead 110 as described below in detail with reference to FIGS. 4A-5C. Further, various mechanisms used to adjust the gap and tilt between the ESC 106 and the showerhead 110 are shown and described in detail with references to FIGS. 6A and 6B.

If plasma is used, an RF generating system 120 generates and outputs an RF voltage to one of the upper electrode 104 and the lower electrode (e.g., the baseplate 112 of the ESC 106). The other one of the upper electrode 104 and the baseplate 112 may be DC grounded, AC grounded, or floating. For example only, the RF generating system 120 may include an RF generator 122 that generates RF power that is fed by a matching and distribution network 124 to the upper electrode 104 or the baseplate 112. In other examples, the plasma may be generated inductively or remotely.

A gas delivery system 130 includes one or more gas sources 132-1, 132-2, . . . , and 132-N (collectively gas sources 132), where N is an integer greater than zero. The gas sources 132 are connected by valves 134-1, 134-2, . . . , and 134-N (collectively valves 134) and mass flow controllers 136-1, 136-2, . . . , and 136-N (collectively mass flow controllers 136) to a manifold 140. A vapor delivery system 142 supplies vaporized precursor to the manifold 140 or another manifold (not shown) that is connected to the processing chamber 102. An output of the manifold 140 is fed to the processing chamber 102.

The controller 160 controls the various components of the substrate processing system 100. For example, the controller 160 is connected to the clamping electrodes 115 in the dielectric plate 114. The controller 160 comprises circuits to measure capacitances between the clamping electrodes 115 and the substrate 108 as described below in detail with reference to FIGS. 4A-4D. The controller 160 comprises circuits to measure capacitances between the clamping electrodes 115 and the showerhead 110 as described below in detail with reference to FIGS. 5A-5C. These circuits are also used for measuring the gap and relative tilt between the ESC 106 and the showerhead 110 as described below in detail with reference to FIGS. 5A-5C. The controller 160 also includes additional circuits to adjust the gap and relative tilt between the ESC 106 and the showerhead 110 as described below in detail with reference to FIGS. 6A and 6B.

Additionally, the controller 160 may sense temperatures of the ESC 106 and the showerhead 110 using sensors (not shown) disposed in the ESC 106 and the showerhead 110. The controller 160 may control the temperatures of the ESC 106, the substrate 108, and the showerhead 110 based on the sensed temperatures. The controller 160 may communicate with a coolant assembly 150 to control coolant flow through the channels 118 in the baseplate 112 of the ESC 106. For example, the coolant assembly 150 may include a coolant pump, a reservoir, and one or more temperature sensors (not shown). The controller 160 may operate the coolant assembly 150 to selectively flow the coolant through the channels 118 to cool the ESC 106. A valve 156 and pump 158 may be used to maintain vacuum in the processing chamber 102 and to evacuate reactants from the processing chamber 102.

FIGS. 2A-2F show examples of various electrode arrangements that can be used in the ESC 106. While different reference numerals are used, it is understood that any of these electrode arrangements can be used as the electrodes 115 shown in FIG. 1. In each of these electrode arrangements, the electrodes are electrically insulated from each other. While not shown for simplicity of illustration, it is understood that a small, finite gap exists between the electrodes to provide electrical isolation between them. FIG. 2A shows an electrode arrangement 200 comprising two inner electrodes 202, 204 (called bipolar electrodes) and an optional outer electrode 206. The inner and outer electrodes 202, 204, and 206 may be arranged in the dielectric plate 114 in the ESC 106 (shown in FIG. 1). The inner and outer electrodes 202, 204, and 206 are electrically isolated from each other by the dielectric material of the dielectric plate 114. The inner electrodes 202, 204 are clamping electrodes that are DC biased to clamp the substrate 108 to the ESC 106. The outer electrode 206 can be DC or RF biased independently of the inner electrodes 202, 204. An example of a biasing system for biasing the electrodes is shown and described below with reference to FIG. 3B.

Electrical connections to the inner and outer electrodes 202, 204, and 206 can be made at locations identified at 208, 210, and 212, respectively. The locations 208, 210, and 212 are generally proximate to the center of the ESC so that the electrical connections can be routed to the controller 160 through the stem portion 117 of the ESC (shown in FIG. 1).

FIGS. 2B-2F show electrode arrangements comprising at least three inner or clamping electrodes according to the present disclosure. While three inner electrodes are shown for simplicity of illustration, additional (e.g., four or more) electrodes may be used. FIG. 2B shows an electrode arrangement 250 comprising three inner electrodes 252, 254, 256 (called tripolar electrodes) and an optional outer electrode 258. The inner and outer electrodes 252, 254, 256, and 258 may be arranged in the dielectric plate 114 in the ESC 106 (shown in FIG. 1). The inner and outer electrodes 252, 254, 256, and 258 are electrically isolated from each other by the dielectric material of the dielectric plate 114. The inner electrodes 252, 254, 256, which are examples of and can be used as the electrodes 115 shown in FIG. 1, are clamping electrodes that are DC biased to clamp the substrate to the ESC. The outer electrode 258 is DC or RF biased independently of the inner electrodes 252, 254, 256. Note that while the inner electrodes 252, 254, 256 are called clamping electrodes, these electrodes need not be used for clamping. Rather, these electrodes can be used for sensing only as described below in addition to being RF antennae with no DC (or AC) clamping function. Similarly, the outer electrode 258 may be DC or RF-biased or may simply serve a sensing function. Alternatively, the outer electrode 258 may serve as a “guard ring” passive electrode function offering an equipotential boundary condition and nothing else. An example of a biasing system for biasing the electrodes is shown and described below with reference to FIG. 3B.

For example, the inner electrodes 252, 254, 256 may be pie-shaped. However, the inner electrodes 252, 254, 256 may be of any other shape. For example, the inner electrodes 252, 254, 256 may (but need not) have the same arc-length, radius, and thickness. For example, the centroids of the inner electrodes 252, 254, 256 may form vertices of an equilateral triangle. For example, the inner electrodes 252, 254, 256 may be preferentially arranged in a plane parallel to an upper surface of the ESC 106 (i.e., parallel to the substrate 108). However, the inner electrodes 252, 254, 256 need not be coplanar and may be arranged in one or more planes that are parallel to the upper surface of the ESC 106.

The outer electrode 258 includes an annular portion 259 that has a greater radius than the inner electrodes 252, 254, 256. The outer electrode 258 includes three spokes 270, 272, 274 that extend radially from the center of the outer electrode 258 and connect to the annular portion 259. The spokes 270, 272, 274 lie in gaps between the inner electrodes 252 and 254, 254 and 256, and 256 and 252, respectively. Stated differently, the inner electrodes 252, 254, 256 lie in the gaps between the spokes 274 and 270, 270 and 272, and 272 and 274, respectively. The spokes 270, 272, 274 may have equal width and may be spaced approximately 120 degrees apart from each other. The inner electrodes 252, 254, 256 may or may not be coplanar with the outer electrode 258. Furthermore, the inner electrodes 252, 254, 256 may or may not have the same thickness as the outer electrode 258. Alternatively, the outer electrode 258 may be of any other shape that can have geometric relationships with the inner electrodes 252, 254, 256 that are analogous to those described above.

Electrical connections to the inner and outer electrodes 252, 254, 256, and 258 are made at locations identified at 260, 262, 264, and 266, respectively. The locations 260, 262, 264, and 266 are generally proximate to the center of the ESC 106 so that the electrical connections can be routed through the stem portion 117 of the ESC to the controller 160 (shown in FIG. 1). The electrical connection for the outer electrode 258 is provided as follows. The three spokes 270, 272, 274 connect the annular portion 259 of the outer electrode 258 to the center. Note that the spokes 270, 272, 274 need not be coplanar with the sensing inner electrodes 252, 254, 256. Although it is cheaper to fabricate them coplanar, the sensing function is enhanced when the spokes 270, 272, 274 are not coplanar with the sensing inner electrodes 252, 254, 256 since the electrical connection is not part of the sensor. The presence of the spokes 270, 272, 274 with a finite width influences the centroid of measurement as the strips of the spokes 270, 272, 274 offer some capacitive coupling to the substrate 108.

FIGS. 2C and 2D show an electrode arrangement 300 comprising the three inner electrodes 252, 254, 256 and an optional disc shaped electrode 302 with an electrical connection 304 at the center of the disc shaped electrode 302. The inner electrodes 252, 254, 256 and the disc shaped electrode 302 may be arranged in the dielectric plate 114 in the ESC 106 (shown in FIG. 1). The inner electrodes 252, 254, 256 and the disc shaped electrode 302 are electrically isolated from each other by the dielectric material of the dielectric plate 114.

The disc shaped electrode 302 has a smaller radius than the inner electrodes 252, 254, 256. The centroids of the inner electrodes 252, 254, 256 may lie on the circumference of the disc shaped electrode 302. The disc shaped electrode 302 is arranged in a plane parallel to the inner electrodes 252, 254, 256. The disc shaped electrode 302 may be arranged above or below the inner electrodes 252, 254, 256 as shown in FIGS. 2C and 2D, respectively. The inner electrodes 252, 254, 256 may or may not have the same thickness as the disc shaped electrode 302. The disc shaped electrode 302 is DC or RF biased independently of the inner electrodes 252, 254, 256. Alternatively, the disc shaped electrode 302 may be of any other shape that can have geometric relationships with the inner electrodes 252, 254, 256 that are analogous to those described above. Other details of the inner electrodes 252, 254, 256 are as already described above with reference to FIG. 2B and are therefore not described again for brevity.

FIG. 2E shows an electrode arrangement 350 comprising the three inner electrodes 252, 254, 256 and three optional outer electrodes 352, 354, 356, which are arc-shaped. The outer electrodes 352, 354, 356 are annular and have a greater radius than the inner electrodes 252, 254, 256. The inner electrodes 252, 254, 256 and the outer electrodes 352, 354, 356 are concentric. The centroids of the inner electrodes 252, 254, 256 are respectively collinear with the centroids of the outer electrodes 352, 354, 356.

The inner electrodes 252, 254, 256 and the outer electrodes 352, 354, 356 may be arranged in the dielectric plate 114 in the ESC 106 (shown in FIG. 1). The inner electrodes 252, 254, 256 and the outer electrodes 352, 354, 356 are electrically isolated from each other by the dielectric material of the dielectric plate 114. The inner electrodes 252, 254, 256 may or may not be coplanar with the outer electrodes 352, 354, 356. Furthermore, the inner electrodes 252, 254, 256 may or may not have the same thickness as the outer electrodes 352, 354, 356. Alternatively, the outer electrodes 352, 354, 356 may be of any other shape that can have geometric relationships with the inner electrodes 252, 254, 256 that are analogous to those described above.

The outer electrodes 352, 354, and 356 are DC or RF biased independently of the inner electrodes 252, 254, 256. The electrode arrangement 350 is suitable for low-temperature applications (e.g., processes performed at <300° C.). In these applications, the stem portion of the ESC can have a greater diameter than the stem portion 117 shown in FIG. 1. For example, the stem portion of the ESC can have a diameter extending up to a periphery (i.e., an outer diameter) of an upper surface of the ESC on which the substrate 108 is arranged during processing. Accordingly, the electrical connections to the outer electrodes 352, 354, and 356 can be made at locations identified at 362, 364, and 366, respectively, which are away from the center of the stem portion of the ESC. Note that the above scheme for providing electrical connections is not limiting, and a different scheme may be used in pedestals built for use in higher temperature processes. Other details of the inner electrodes 252, 254, 256 are as described above with reference to FIG. 2B and are therefore not described again for brevity. Another electrode arrangement shown in FIG. 2F is described below together with a biasing system shown in FIG. 3C.

Before describing the biasing system for biasing the electrodes, the sensing systems to sense substrate states using the electrodes, and systems for measuring the gap and relative tilt between the ESC and the showerhead, and an example of implementing connections of electrodes and other electrical elements in the ESC to control circuits are described. Throughout the present disclosure, similar connections for electrodes are presumed and are not shown in other figures in similar detail. Instead, the connections of the electrodes and the electrodes themselves are shown in these other figures only schematically to simplify illustrations of other features of the present disclosure.

FIG. 3A shows an example of implementing connections of electrodes and other electrical elements in the ESC 106 to control circuits. For example, only the three inner electrodes 252, 254, 256 and their connections are shown. It is understood that other electrodes (e.g., the outer electrode 258, the disc shaped electrode 302, etc.) can be similarly connected to the control circuits.

For example, to connect the three inner electrodes 252, 254, 256 to the control circuits, through holes 370, 372, and 374 are drilled through the dielectric plate 114 and the baseplate 112 as shown. Conductors 376, 378, 380 are routed via the through holes 370, 372, and 374, respectively. While not shown, the conductors 376, 378, 380 are electrically insulated from the baseplate 112. First ends of the conductors 376, 378, 380 are connected to the three inner electrodes 252, 254, 256 at locations 260, 262, 264, respectively. Second ends of the conductors 376, 378, 380 are connected to a first PCB 382 that is fixed to the bottom of the baseplate 112.

The first PCB 382 is connected to a second PCB 384 that is fixed to a facility plate 386. The first PCB 382 and the second PCB 384 are connected to each other by a plurality of spring-loaded pin connections 383. The pin connections 383 are arranged on the second PCB 384. The first PCB 382 includes a plurality of pads (not shown). The tips of the pin connections 383 contact the corresponding pads on the first PCB 382. The second PCB 384 is connected to a power supply and control circuit 390. The power supply and control circuit 390 supplies power to the second PCB 384. The first PCB 382 receives the power from the second PCB 384 and supplies the power to the three inner electrodes 252, 254, 256 via the conductors 376, 378, 380, respectively.

The first PCB 382 or the second PCB 384 may include switches (shown in FIGS. 3B-6B) that are used to selectively connect the electrodes in the dielectric plate 114 to the power supply and control circuit 390 and to the controller 160. These switches are controlled by the power supply and control circuit 390 and/or by the controller 160. The first PCB 382 or the second PCB 384 may include blocking circuitry used when both RF and DC biasing are utilized. The blocking circuitry comprises inductors and capacitors (see FIGS. 3B-3D). The controller 160 controls the power supply and control circuit 390. The controller 160 may communicate with the first PCB 382 and/or the second PCB 384 directly or via the power supply and control circuit 390.

The operation of the switches and the connections of the electrodes to the power supply and control circuit 390 are described below with reference to FIG. 3B. The operation of the switches and the connections of the electrodes to the controller 160 for measuring the gap and relative tilt according to the present disclosure are described below in further detail with reference to FIGS. 4A-5C. For illustrative convenience, in FIGS. 3B-6B, the switches are shown as being disposed in the facility plate 386, which is used to collectively refer to the first and second PCBs 382, 384. Further, for simplicity of illustration, in FIGS. 4B-5C, the baseplate 112 is omitted to keep the focus on the electrodes and switches.

For completeness, the first PCB 382 additionally includes electrical connections to heaters and temperature sensors (not shown) disposed in a heating plate 388. The first PCB 382 also includes power and signal distribution hardware. The first PCB 382 receives power from the second PCB 384 and supplies the power to the heaters in the heating plate 388. Further, a plurality of temperature probes 392 that sense the temperature of the dielectric plate 114 are arranged in the baseplate 112. Additionally, a temperature probe 394 that senses the temperature of the baseplate 112 is also arranged in the baseplate 112. The first PCB 382 includes connections to the temperature probes 392, 394. The first PCB 382 receives signals from the temperature probes 392, 394. The second PCB 384 receives the signals from the first PCB 382. The second PCB 384 supplies the signals to the power supply and control circuit 390. The power supply and control circuit 390 controls the power to the heaters in the heating plate 388 based on the signals from the temperature probes 392, 394. Additionally, the power supply and control circuit 390 also controls the flow of coolant through the cooling channels 118 based on the signals from the temperature probes 392, 394.

FIGS. 3B and 3C show examples of biasing systems to bias electrodes in the ESC 106. FIG. 3B shows an example of a biasing system 400 implementing a monopolar clamping system, and FIG. 3C shows an example of a biasing system 400-1 implementing a bipolar clamping system. The biasing systems 400 and 400-1 are collectively called the biasing system 400. For illustrative purposes, the examples show only the three inner electrodes 252, 254, 256 and the outer electrode 258 shown in FIG. 2B. However, it is understood that the biasing system 400 can be adapted and used to bias other electrode arrangements shown in FIGS. 2C-2F as well.

The biasing system 400 comprises the controller 160 and switches S1 and S2 in FIG. 3B and switch S1 in FIG. 3C (collectively the switches 402). The switches 402 are optional and are disposed in the facility plate 386 when used. For example, in FIG. 3B, the inner electrodes 252, 254, 256 and the outer electrode 258 are connected to a DC power supply 406 in the power supply and control circuit 390 via the switch S2. Alternatively, the inner electrodes 252, 254, 256 and the outer electrode 258 can be connected to an RF power source 410 in the power supply and control circuit 390 via the switch S1.

In FIGS. 3B and 3C, the controller 160 controls the switches S1 and S2. In FIG. 3B, when switch S2 is closed, DC power from the DC power supply 406 is applied to the inner electrodes 252, 254, 256 and the outer electrode 258. When switch S1 is closed, RF power from the RF power source 410 is applied to the inner electrodes 252, 254, 256 and the outer electrode 258. In FIG. 3C, DC power from the DC power supply 406 is applied to the inner electrodes 252, 254, 256. Additionally, when switch S1 is closed, RF power from the RF power source 410 is applied to the outer electrode 258.

Since the biasing systems 400 shown in FIGS. 3B and 3C (and in FIG. 3D) use both DC and RF biasing, a blocking circuitry comprising DC and RF blocking elements such as inductors and capacitors is used. In general, inductors block high frequency from damaging the DC supplies, and capacitors block low frequency like DC from damaging the RF generators. While the inductors and capacitors are shown in the power supply and control circuit 390, the inductors and the capacitors may be disposed in the facility plate 386. In practice, these generalized elements may be implemented as local circuit networks tuned to block a particular frequency to protect the adjacent power source from damage or interference due to the other frequencies present in the system.

Note that as mentioned above with reference to FIG. 2B-2E, although three inner electrodes 252, 254, 256 are shown for illustrative purposes, more than three inner electrodes can be used. If a fourth inner electrode is used, while the fourth inner electrode would be unnecessary from a measurement perspective, the fourth inner electrode can simplify DC biasing for electrostatic clamping because the four electrodes can be used in pairs. For example, a first pair of electrodes can be connected to a first tap of a bipolar voltage supply, and a second pair of electrodes can be connected to a second tap of the bipolar voltage supply.

For example, FIG. 2F shows an electrode arrangement 310 comprising four inner electrodes 312, 314, 316, 318 and an optional outer electrode 320. The inner and outer electrodes 312, 314, 316, 318 and 320 may be arranged in the dielectric plate 114 in the ESC 106 (shown in FIG. 1). The inner and outer electrodes 312, 314, 316, 318 and 320 are electrically isolated from each other by the dielectric material of the dielectric plate 114. The inner electrodes 312, 314, 316, 318 are clamping electrodes that are DC biased to clamp the substrate 108 to the ESC 106. The outer electrode 320 is DC or RF biased independently of the inner electrodes 312, 314, 316, 318. An example of a biasing system for biasing the electrodes is shown and described below with reference to FIG. 3C.

For example, the inner electrodes 312, 314, 316, 318 may be pie-shaped. However, the inner electrodes 312, 314, 316, 318 may be of any other shape. For example, the inner electrodes 312, 314, 316, 318 may (but need not) have the same arc-length, radius, and thickness. For example, the centroids of the inner electrodes 312, 314, 316, 318 may form vertices of a square. For example, the inner electrodes 312, 314, 316, 318 may be preferentially arranged in a plane parallel to an upper surface of the ESC 106 (i.e., parallel to the substrate 108). However, the inner electrodes 312, 314, 316, 318 need not be coplanar and may be arranged in one or more planes that are parallel to the upper surface of the ESC 106.

The outer electrode 320 includes an annular portion 322 that has a greater radius than the inner electrodes 312, 314, 316, 318. The outer electrode 320 includes four spokes 324, 326, 328, 330 that extend radially from the center of the outer electrode 320 and connect to the annular portion 322. The spokes 324, 326, 328, 330 lie in gaps between the inner electrodes 312 and 314, 314 and 316, 316 and 318, and 318 and 320, respectively. Stated differently, the inner electrodes 312, 314, 316, 318 lie in the gaps between the spokes 330 and 324, 324 and 326, 326 and 328, and 328 and 330, respectively. The spokes 324, 326, 328, 330 may have equal width and may be spaced approximately 90 degrees apart from each other. The inner electrodes 312, 314, 316, 318 may or may not be coplanar with the outer electrode 320. Furthermore, the inner electrodes 312, 314, 316, 318 may or may not have the same thickness as the outer electrode 320. Alternatively, the outer electrode 320 may be of any other shape that can have geometric relationships with the inner electrodes 312, 314, 316, 318 that are analogous to those described above.

Electrical connections to the inner and outer electrodes 312, 314, 316, 318 and 320 are made at locations identified at 332, 334, 336, 338, and 340, respectively. The locations 332, 334, 336, 338, and 340 are generally proximate to the center of the ESC 106 so that the electrical connections can be routed through the stem portion 117 of the ESC to the controller 160 (shown in FIG. 1). The electrical connection for the outer electrode 320 is provided as follows. The four spokes 324, 326, 328, 330 connect the annular portion 322 of the outer electrode 320 to the center. Note that the spokes 324, 326, 328, 330 need not be coplanar with the sensing inner electrodes 312, 314, 316, 318. Although it is cheaper to fabricate them coplanar, the sensing function is enhanced when the spokes 324, 326, 328, 330 are not coplanar with the sensing inner electrodes 312, 314, 316, 318 since the electrical connection is not part of the sensor. The presence of the spokes 324, 326, 328, 330 with a finite width influences the centroid of measurement as the strips of the spokes 324, 326, 328, 330 offer some capacitive coupling to the substrate 108.

FIG. 3D shows an example of a biasing system 401 to bias electrodes in the ESC 106. For simplicity, only an example of a bipolar clamping system is shown. It is understood that a monopolar clamping system can also be implemented. For illustrative purposes, the example shows the four inner electrodes 312, 314, 316, 318 and the outer electrode 320 shown in FIG. 2F as electrodes E1-E5, respectively. The biasing system 401 comprises the controller 160 and switches S1, S2, S3, S4, and S5 (collectively the switches 403). The switches 403 are optional and are disposed in the facility plate 386 when used. While the inductors are shown in the power supply and control circuits 390 and the capacitors are shown in the facility plate 386, the inductors and capacitors can be disposed in the power supply and control circuits 390 or in the facility plate 386. The inner electrodes 312, 314, 316, 318 are connected in pairs to one or more DC power supplies. For example, a first pair of the inner electrodes 312, 314 (E1, E2) and a second pair of the inner electrodes 316, 318 (E3, E4) are respectively connected the DC power supplies 404, 408 in the power supply and control circuit 390 via the switches 403. In some examples, a single bipolar voltage supply may be used, and the first pair of the inner electrodes 312, 314 (E1, E2) may be connected to one tap and the second pair of the inner electrodes 316, 318 (E3, E4) may be connected to the other tap of the bipolar voltage supply.

In some examples, the electrodes may be paired differently. For example, instead of pairing adjacent electrodes as described above, opposite electrodes (E1, E3) and (E2, E4) may be paired. In some examples, the inner electrodes 312, 314, 316, 318 may be connected to a single DC power supply via a single switch. Alternatively, while not shown, the inner electrodes 312, 314, 316, 318 may be connected to one or more RF power sources instead. The outer electrode 320 may be connected to an RF power source 410 in the power supply and control circuit 390 via the switch S5. Alternatively, while not shown, the outer electrode 320 may be connected to a DC power supply.

The controller 160 operates the switches S1-S4 to supply DC power (or AC power if used) to the inner electrodes 312, 314, 316, 318 to clamp the substrate 108 to the dielectric plate 114. The controller 160 operates the switch S5 to supply RF power to provide a radially differential RF bias to the substrate 108. In some examples, a DC power source may be used instead of the RF power source 410 to provide DC bias to the substrate 108. Examples of various clamping schemes that can be employed using the electrode arrangements shown in FIGS. 2B-2F and using the biasing systems shown in FIGS. 3B-3D are shown and described below with reference to FIGS. 11A and 11B.

FIGS. 4A-4D show examples of sensing systems used for sensing states of a substrate (e.g., the substrate 108 shown in FIG. 1). The sensing systems utilize different arrangements of electrodes in the ESC 106 to sense the states of the substrate. The states of a substrate include substrate absent, substrate present, and substrate clamped. FIG. 4A shows a sensing system that senses the states of the substrate 108 using a single capacitance measurement circuit and using only the three inner electrodes 252, 254, 256 (i.e., the three clamping electrodes) disposed in the ESC 106. FIG. 4B shows a sensing system that senses the states of the substrate 108 using the three inner electrodes 252, 254, 256 and a fourth electrode (e.g., the outer electrode 258 or the disc shaped inner electrode 302) disposed in the ESC 106. FIG. 4C shows a sensing system that senses the states of the substrate 108 using the three inner electrodes 252, 254, 256 and the three outer electrodes 352, 354, 356 disposed in the ESC 106. FIG. 4D shows a sensing system that senses the states of the substrate 108 using three separate capacitance measurement circuits. Throughout the following description, the substrate 108 is electrically conductive.

In FIG. 4A, a sensing system 450 comprises the inner electrodes 252, 254, 256 and a set of switches S1-S6 (collectively the switches 452) disposed in the facility plate 386 of the ESC 106 (shown in FIG. 3A). The sensing system 450 further comprises the controller 160 that includes a capacitance measurement circuit 460.

A first capacitance 420 is formed between the inner electrode 252 and the substrate 108, with the dielectric material of the dielectric plate 114 acting as dielectric between the inner electrode 252 and the substrate 108. A second capacitance 422 is formed between the inner electrode 254 and the substrate 108, with the dielectric material of the dielectric plate 114 acting as dielectric between the inner electrode 254 and the substrate 108. A third capacitance 424 is formed between the inner electrode 256 and the substrate 108, with the dielectric material of the dielectric plate 114 acting as dielectric between the inner electrode 256 and the substrate 108.

The values of the first, second, and third capacitances change based on whether the substrate is absent, present, or clamped. The values of the first, second, and third capacitances are inversely proportional to the distance between the electrodes 252, 254, 256 and the substrate 108. The values of the first, second, and third capacitances increase as the distance between the electrodes 252, 254, 256 and the substrate 108 decreases. The values of the first, second, and third capacitances are relatively low (e.g., less than or equal to a first threshold) when the substrate 108 is absent. The values of the first, second, and third capacitances are relatively high (e.g., greater than the first threshold but less than or equal to a second threshold that is higher than the first threshold) when the substrate 108 is present but the substrate 108 is not clamped. The values of the first, second, and third capacitances are very high (e.g., greater than the second threshold) when the substrate 108 is clamped.

The controller 160 controls the switches 452 to connect different pairs of the first, second, and third capacitances to the capacitance measurement circuit 460. For example, with switches S1 and S5 (or S4 and S2) closed and all other switches open, the first and second capacitances are connected to each other in series, and the series combination of the first and second capacitances is connected to the capacitance measurement circuit 460. With switches S1 and S6 (or S4 and S3) closed and all other switches open, the first and third capacitances are connected to each other in series, and the series combination of the second and third capacitances is connected to the capacitance measurement circuit 460. With switches S2 and S6 (or S5 and S3) closed and all other switches open, the second and third capacitances are connected to each other in series, and the series combination of the first and third capacitances is connected to the capacitance measurement circuit 460.

For example, the capacitance measurement circuit 460 may include an oscillator circuit or a PLL. For example, the capacitance measurement circuit 460 may include one or more passive components (e.g., resistors). The two inputs or connections to the capacitance measurement circuit 460 form a timing control (i.e., a period) of the capacitance measurement circuit 460. When any pair of the first, second, and third capacitances is connected to the capacitance measurement circuit 460 using the switches 452 as described above, the time constant and frequency of oscillation of the capacitance measurement circuit 460 changes depending on the variation in capacitance values of the first, second, and third capacitances. Since the capacitance values vary depending on whether the substrate 108 is absent, present but not clamped, or present and clamped, the time constant and the frequency of oscillation of the capacitance measurement circuit 460 also change depending on whether the substrate 108 is absent, present but not clamped, or present and clamped. The capacitance measurement circuit 460 measures the change in capacitance by measuring the change in the frequency of oscillation of the capacitance measurement circuit 460. The controller 160 determines if the substrate 108 is absent, present but not clamped, or present and clamped based on the change in the frequency of oscillation of the capacitance measurement circuit 460.

Note that any one of the three capacitance measurements (i.e., any two of the three electrodes 252, 254, 256) suffices to determine the state of the substrate 108. However, at least three electrodes 252, 254, 256 are used to measure a gap and a relative tilt between the ESC 106 and the showerhead 110 as described below with reference to FIG. 5A. Briefly, the ESC 106 is moved close to (e.g., within 1 mm of) the showerhead 110. The dielectric plate 114 of the ESC 106 acts as dielectric between the electrodes 252, 254, 256 and the showerhead 110. Capacitances between the electrodes 252, 254, 256 and the showerhead 110 can be measured similar to the capacitances measured between the electrodes 252, 254, 256 and the substrate 108 as described above. Then the gap and relative tilt between the ESC 106 and the showerhead 110 can be measured as described below with reference to FIG. 5A.

In FIG. 4B, a sensing system 500 comprises the inner electrodes 252, 254, 256 and a fourth electrode 504. For example, the outer electrode 258 is shown as the fourth electrode 504. Alternatively, the disc shaped electrode 302 may be used as the fourth electrode 504. The sensing system 500 comprises a set of switches S1-S4 (collectively the switches 502) disposed in the facility plate 386 of the ESC 106 (shown in FIG. 3A). The sensing system 500 further comprises the controller 160 that comprises the capacitance measurement circuit 460.

The first, second, and third capacitances are formed between the electrodes 252, 254, 256 and the substrate 108 as described above with reference to FIG. 4A. In addition, a fourth capacitance is formed between the fourth electrode 504 and the substrate 108, with the dielectric material of the dielectric plate 114 acting as dielectric between the fourth electrode 504 and the substrate 108. The controller 160 controls the switches 502 to connect different pairs of the first through fourth capacitances to the capacitance measurement circuit 460 as follows.

For example, with switches S1 and S4 closed and switches S2 and S3 open, the first and fourth capacitances are connected to each other in series, and the series combination of the first and fourth capacitances is connected to the capacitance measurement circuit 460. With switches S2 and S4 closed and switches S1 and S3 open, the second and fourth capacitances are connected to each other in series, and the series combination of the second and fourth capacitances is connected to the capacitance measurement circuit 460. With switches S3 and S4 closed and switches S1 and S2 open, the third and fourth capacitances are connected to each other in series, and the series combination of the third and fourth capacitances is connected to the capacitance measurement circuit 460.

When any pair of capacitances comprising the fourth capacitance and any of the of the first, second, and third capacitances is connected to the capacitance measurement circuit 460 using the switches 502 as described above, the time constant and frequency of oscillation of the capacitance measurement circuit 460 changes depending on the variation in capacitance values of the first, second, third, and fourth capacitances. Since the capacitance values vary depending on whether the substrate 108 is absent, present but not clamped, or present and clamped, the time constant and the frequency of oscillation of the capacitance measurement circuit 460 also change depending on whether the substrate 108 is absent, present but not clamped, or present and clamped. All other features of the capacitance measurement circuit 460 are the same as those described above with reference to FIG. 4A and are therefore not described again for brevity.

To measure a gap and a relative tilt between the ESC 106 and the showerhead 110, the ESC 106 is moved close to (e.g., within 1 mm of) the showerhead 110. The dielectric plate 114 of the ESC 106 acts as dielectric between the electrodes 252, 254, 256, 504 and the showerhead 110. Capacitances between the electrodes 252, 254, 256, 504 and the showerhead 110 (i.e., effective capacitance between the electrodes and the surface of the dielectric plate 114 as well as the capacitance from the surface of the dielectric plate 114 to the face of the showerhead 110) can be measured similar to the capacitances measured between the electrodes 252, 254, 256, 504 and the substrate 108 as described above. Then the gap and relative tilt between the ESC 106 and the showerhead 110 can be measured as described below with reference to FIG. 5B.

In FIG. 4C, a sensing system 550 comprises the inner electrodes 252, 254, 256 and the three outer electrodes 352, 354, 356. The sensing system 500 comprises a set of switches S1-S6 (collectively the switches 552) disposed in the facility plate 386 of the ESC 106 (shown in FIG. 3A). The sensing system 550 further comprises the controller 160 that comprises the capacitance measurement circuit 460.

The first, second, and third capacitances are formed between the electrodes 252, 254, 256 and the substrate 108 as described above with reference to FIG. 4A. In addition, fourth, fifth, and sixth capacitances are formed between the electrodes 352, 354, 356 and the substrate 108, with the dielectric material of the dielectric plate 114 acting as dielectric between the electrodes 352, 354, 356 and the substrate 108. The controller 160 controls the switches 552 to connect different pairs of the first through sixth capacitances to the capacitance measurement circuit 460 as follows.

For example, with switches S1 and S4 closed and all other switches open, the first and fourth capacitances are connected to each other in series, and the series combination of the first and fourth capacitances is connected to the capacitance measurement circuit 460. With switches S2 and S5 closed and all other switches open, the second and fifth capacitances are connected to each other in series, and the series combination of the second and fifth capacitances is connected to the capacitance measurement circuit 460. With switches S3 and S6 closed and all other switches open, the third and sixth capacitances are connected to each other in series, and the series combination of the third and sixth capacitances is connected to the capacitance measurement circuit 460.

When any pair of capacitances (first and fourth, second and fifth, or third and sixth) is connected to the capacitance measurement circuit 460 using the switches 552 as described above, the time constant and frequency of oscillation of the capacitance measurement circuit 460 changes depending on the variation in capacitance values of the first through sixth capacitances. Since the capacitance values vary depending on whether the substrate 108 is absent, present but not clamped, or present and clamped, the time constant and the frequency of oscillation of the capacitance measurement circuit 460 also change depending on whether the substrate 108 is absent, present but not clamped, or present and clamped. All other features of the capacitance measurement circuit 460 are the same as those described above with reference to FIG. 4A and are therefore not described again for brevity.

FIG. 4D shows a sensing system 551 that can be used instead of the sensing system 550. The sensing system 551 uses three independent capacitance measurement circuits 460-1, 4602, and 460-3 that are respectively connected permanently to three pairs of electrodes. For example, a first capacitance measurement circuit 460-1 is connected to the electrode pair E1/E2; the second capacitance measurement circuit 460-2 is connected to the electrode pair E1/E3; and third capacitance measurement circuit 460-3 is connected to the electrode pair E2/E3. Using independent capacitance measurement circuits allows making the capacitance measurements simultaneously rather than sequentially and eliminates (or reduces the number of) switches.

To measure a gap and a relative tilt between the ESC 106 and the showerhead 110, the ESC 106 is moved close to (e.g., within 1 mm of) the showerhead 110. The dielectric plate 114 of the ESC 106 acts as dielectric between the electrodes 252, 254, 256, 352, 354, 356 and the showerhead 110. Capacitances between the electrodes 252, 254, 256, 352, 354, 356 and the showerhead 110 can be measured similar to the capacitances measured between the electrodes 252, 254, 256, 352, 354, 356 and the substrate 108 as described above. Then the gap and relative tilt between the ESC 106 and the showerhead 110 can be measured as described below in detail with reference to FIG. 5C.

FIGS. 5A-5D show examples of systems for measuring the gap (e.g., mean showerhead-pedestal gap) and relative tilt (i.e., magnitude of tilt and direction of tilt (i.e., tilt axis orientation)) between the ESC 106 and the showerhead 110. These systems utilize the sensing systems shown in FIGS. 4A-4D. In the sensing systems of FIGS. 4A-4D, the substrate 108 forms one plate of the capacitances, and the various electrodes in the ESC 106 form the other plate of the capacitances, with the dielectric plate 114 acting as the dielectric between the two plates. In the systems of FIGS. 5A-5D, the showerhead 110 forms one plate of the capacitances, and the various electrodes in the ESC 106 form the other plate of the capacitances, with the dielectric plate 114 acting as the dielectric between the two plates.

FIG. 5A shows that the sensing system 450, which senses the states of the substrate 108 using only the three inner electrodes 252, 254, 256, is used to measure the gap and tilt between the ESC 106 and the showerhead 110. FIG. 5B shows that the sensing system 500, which senses the states of the substrate 108 using the three inner electrodes 252, 254, 256 and the fourth electrode 504, is used to measure the gap and tilt between the ESC 106 and the showerhead 110. FIG. 5C shows that the sensing system 550, which senses the states of the substrate 108 using the three inner electrodes 252, 254, 256 and the three outer electrodes 352, 354, 356, is used to measure the gap and tilt between the ESC 106 and the showerhead 110. Using more than three electrodes as shown in FIGS. 5B and 5C improves the resolution with which the gap and tilt between the ESC 106 and the showerhead 110 can be measured. These systems are now described in detail.

FIG. 5A shows a system 600 for measuring the gap and relative tilt between the ESC 106 and the showerhead 110. The system 600 measures the gap and relative tilt by utilizing the three inner electrodes 252, 254, 256 and the switches 452 disposed in the facility plate 386 of the ESC 106 (shown in FIG. 3A). The system 600 measures the gap and relative tilt using the capacitance measurement circuit 460 included in the controller 160 as follows.

To measure the gap and relative tilt between the ESC 106 and the showerhead 110, the ESC 106 is moved close to the showerhead 110 (e.g., within 1 mm of the showerhead 110). Three capacitance measurements are made using the capacitance measurement circuit 460. Specifically, the three inner electrodes 252, 254, 256 are paired using the switches 452, and each of the three electrode pairs is sequentially connected to the capacitance measurement circuit 460 as described above with reference to FIG. 4A. The capacitance measurement circuit 460 measures three capacitances between each of the three electrode pairs and the showerhead 110.

The three capacitance measurements can be made sequentially using the capacitance measurement circuit 460 as described above with reference to FIG. 4A. Alternatively, while not shown, the three capacitance measurements can be made simultaneously using three separate sets of the capacitance measurement circuit 460. Due to the arrangement of the three inner electrodes 252, 254, 256 in the ESC 106, the three capacitance measurements are spatially separated and provide three relative displacements of the three inner electrodes 252, 254, 256 relative to the showerhead 110.

The controller 160 comprises a gap measurement circuit 470 and a tilt measurement circuit 472. The gap measurement circuit 470 measures the gap (i.e., the distance) between the ESC 106 and the showerhead 110 from the three relative displacements of the three inner electrodes 252, 254, 256 relative to the showerhead 110. The tilt measurement circuit 472 calculates a magnitude and a direction of the tilt based on the three relative displacements. For example, the tilt measurement circuit 472 calculates the magnitude and the direction of the tilt by fitting a plane to the three relative displacements and by calculating an angle between the fitted plane and a horizontal plane.

FIG. 5B shows a system 650 for measuring the gap and relative tilt between the ESC 106 and the showerhead 110. The system 650 measures the gap and relative tilt by utilizing the three inner electrodes 252, 254, 256, the fourth electrode 504 (e.g., the outer electrode 258 or the disc shaped electrode 302), and the switches 502 disposed in the facility plate 386 of the ESC 106 (shown in FIG. 3A). The system 650 measures the gap and relative tilt using the capacitance measurement circuit 460 included in the controller 160 as follows.

To measure the gap and relative tilt between the ESC 106 and the showerhead 110, the ESC 106 is moved close to the showerhead 110 (e.g., within 1 mm of the showerhead 110). Three capacitance measurements are made using the capacitance measurement circuit 460. Specifically, each of the three inner electrodes 252, 254, 256 is paired with the fourth electrode 504, and each of the three electrode pairs is sequentially connected to the capacitance measurement circuit 460 using the switches 502 as described above with reference to FIG. 4B. The capacitance measurement circuit 460 measures three capacitances between each of the three electrode pairs and the showerhead 110.

The three capacitance measurements can be made sequentially using the capacitance measurement circuit 460 as described above with reference to FIG. 4B. Alternatively, the three capacitance measurements can be made simultaneously using separate sets of the capacitance measurement circuit 460 (e.g., see FIG. 4D). Due to the arrangement of the electrodes 252, 254, 256, 504 in the ESC 106, the three capacitance measurements are spatially separated and provide three relative displacements of the three inner electrodes 252, 254, 256 relative to the showerhead 110.

The controller 160 comprises the gap measurement circuit 470 and the tilt measurement circuit 472. The gap measurement circuit 470 measures the gap (i.e., the distance) between the ESC 106 and the showerhead 110 from the three relative displacements of the three inner electrodes 252, 254, 256 relative to the showerhead 110. The tilt measurement circuit 472 calculates the magnitude and the direction of the tilt based on the three relative displacements. For example, the tilt measurement circuit 472 calculates the magnitude and the direction of the tilt by fitting a plane to the three relative displacements and by calculating an angle between the fitted plane and a horizontal plane.

FIG. 5C shows a system 700 for measuring the gap and relative tilt between the ESC 106 and the showerhead 110. The system 700 measures the gap and relative tilt by utilizing the three inner electrodes 252, 254, 256; the three outer electrodes 352, 354, 356; and the switches 552 disposed in the facility plate 386 of the ESC 106 (shown in FIG. 3A). The system 700 measures the gap and relative tilt using the capacitance measurement circuit 460 included in the controller 160 as follows.

To measure the gap and relative tilt between the ESC 106 and the showerhead 110, the ESC 106 is moved close to the showerhead 110 (e.g., within 1 mm of the showerhead 110). Three capacitance measurements are made using the capacitance measurement circuit 460. Specifically, the three inner electrodes 252, 254, 256 are respectively paired with the three outer electrodes 352, 354, 356; and each of the three electrode pairs is sequentially connected to the capacitance measurement circuit 460 using the switches 552 as described above with reference to FIG. 4C. Three capacitances are measured between each of the three electrode pairs and the showerhead 110.

The three capacitance measurements can be made sequentially using the capacitance measurement circuit 460 as described above with reference to FIG. 4B. Alternatively, the three capacitance measurements can be made simultaneously using separate sets of the capacitance measurement circuit 460 (e.g., see FIG. 4D). Due to the arrangement of the electrodes 252, 254, 256, 352, 354, 356 in the ESC 106, the three capacitance measurements are spatially separated and provide three relative displacements of the three inner electrodes 252, 254, 256 relative to the showerhead 110.

The controller 160 comprises the gap measurement circuit 470 and the tilt measurement circuit 472. The gap measurement circuit 470 measures the gap (i.e., the distance) between the ESC 106 and the showerhead 110 from the three relative displacements of the three inner electrodes 252, 254, 256 relative to the showerhead 110. The tilt measurement circuit 472 calculates the magnitude and the direction of the tilt based on the three relative displacements. For example, the tilt measurement circuit 472 calculates the magnitude and the direction of the tilt by fitting a plane to the three relative displacements and by calculating an angle between the fitted plane and a horizontal plane.

In some examples, the gap between the ESC 106 and the showerhead 110 may be relatively large, which makes the capacitances between the electrodes in the ESC 106 and the showerhead 110 very small and difficult to measure. In such systems, plasma may be struck between the ESC 106 and the showerhead 110. The presence of plasma between the ESC 106 and the showerhead 110 changes the impedances between the electrodes in the ESC 106 and the showerhead 100 and facilitates the capacitance measurements despite the large gap between the ESC 106 and the showerhead 110. For example, the density and electrical properties of the plasma depend on the gap between the ESC 106 and the showerhead 110, which in turn influence the capacitance measurements. Therefore, the gap and relative tilt between the ESC 106 and the showerhead 110 can be measured based on the capacitance measurements carried out in the presence of the plasma.

FIG. 5D shows a system 601 for measuring the gap and relative tilt between the ESC 106 and the showerhead 110 using plasma 603 struck between the ESC 106 and the showerhead 110. For example, the plasma 603 may be struck between the ESC 106 and the showerhead 110 as described above with reference to FIG. FIG. 1 except without the substrate present. The system 601 is identical to the system 600 shown and described above with reference to FIG. 5A except for the addition of the plasma 603. The system 601 measures the gap and relative tilt using the capacitance measurement circuit 460 included in the controller 160 as described above with reference to FIG. 5A. While not shown, the systems shown in FIGS. 5B and 5C can also employ plasma to measure the gap and relative tilt between the ESC 106 and the showerhead 110.

FIGS. 6A and 6B show examples of mechanisms that can be used for adjusting the gap and relative tilt between the ESC 106 and the showerhead 110. For example, gimbals or similar mechanisms, which provide at least three angular degrees of freedom and allow at least three angular adjustments, can be used with the ESC 106, the showerhead 110, or both to adjust the gap and relative tilt between the ESC 106, the showerhead 110. Alternatively, actuators such as threaded features, which can be moved with three angular degrees of freedom using respective motors, may be used with the ESC 106, the showerhead 110, or both to adjust the gap and relative tilt between the ESC 106, the showerhead 110. FIG. 6A shows examples of actuators and motors used with the ESC 106 (i.e., the ESC 106 is gimballed). FIG. 6B shows examples of actuators and motors used with the showerhead 110 (i.e., the showerhead 110 is gimballed). For example only, while three actuators are shown and described below with reference to FIGS. 6A and 6B, only two actuators can be used to adjust the gap and relative tilt between the ESC 106 and the showerhead 110.

FIG. 6A shows a system 750 for measuring and adjusting the gap and relative tilt between the ESC 106 and the showerhead 110. The system 750 comprises the ESC 106 including the dielectric plate 114, the baseplate 112, the stem portion 117, and the actuator 119. The dielectric plate 114 includes electrodes 754 and switches 756, which may include any of the electrode arrangements and corresponding switches shown in FIGS. 5A-5D.

The system 750 further comprises the showerhead 110 and the controller 160. The showerhead 110 is mounted to a top plate 752 of the processing chamber 102. The controller 160 comprises the capacitance measurement circuit 460, the gap measurement circuit 470, and the tilt measurement circuit 472. The controller 160 further comprises a gap and tilt adjustment circuit (hereinafter the adjustment circuit) 480 to adjust the gap and relative tilt between the ESC 106 and the showerhead 110. The capacitance measurement circuit 460, the gap measurement circuit 470, and the tilt measurement circuit 472 measure the gap and relative tilt between the ESC 106 and the showerhead 110 as described above with reference to FIGS. 5A-5D, and are therefore not described again for brevity.

Three actuators are mounted to the ESC 106 to adjust the gap and relative tilt between the ESC 106 and the showerhead 110 as follows. In addition to the actuator 119 that is mounted to the stem portion 117 of the ESC 106, actuators 810 and 812 are mounted to a cylindrical sidewall 804 of the processing chamber 102 using respective mounting assemblies 820, 822. Each of the actuators 810, 812, and 119 has three angular degrees of freedom. Of the three degrees of freedom, two degrees of freedom are used to adjust the relative tilt, and one degree of freedom is used to adjust the gap between the ESC 106 and the showerhead 110. The actuators 810, 812, and 119 are driven by respective motors 830, 832, and 834. The adjustment circuit 480 adjusts the gap and relative tilt between the ESC 106 and the showerhead 110 by controlling the motors 830, 832, and 834 as follows.

In use, the gap measurement circuit 470 measures the gap between the ESC 106 and the showerhead 110 using any of the systems 650, 700, or 750 depending on the electrode configuration used in the ESC 106, as described above with reference to FIGS. 5A-5D. The tilt measurement circuit 472 measures the relative tilt between the ESC 106 and the showerhead 110 using any of the systems 650, 700, or 750 depending on the electrode configuration used in the ESC 106, as described above with reference to FIGS. 5A-5D.

If no tilt or a specific tilt (magnitude and direction) is desired, any detected tilt may be adjusted as follows to achieve the desired tilt. Based on the measured tilt and the desired tilt, the adjustment circuit 480 adjusts the tilt of the ESC 106 relative to the showerhead 110 (magnitude and direction) as desired (i.e., no tilt or desired tilt) by controlling the motors 830, 832, and 834 that drive the respective actuators 810, 812, and 119. Based on the measured gap and the desired gap, the adjustment circuit 480 controls the gap between the ESC 106 and the showerhead 110 by controlling the motors 830, 832, and 834 that drive the respective actuators 810, 812, and 119.

FIG. 6B shows a system 800 for measuring and adjusting the gap and relative tilt between the ESC 106 and the showerhead 110. The system 800 comprises the ESC 106 including the dielectric plate 114, the baseplate 112, the stem portion 117, and the actuator 119. The dielectric plate 114 includes electrodes 754 and switches 756, which may include any of the electrode arrangements and corresponding switches shown in FIGS. 5A-5D.

The system 800 further comprises the showerhead 110 and the controller 160. The showerhead 110 is mounted to the top plate 752 of the processing chamber 102. The controller 160 comprises the capacitance measurement circuit 460, the gap measurement circuit 470, and the tilt measurement circuit 472. The controller 160 further comprises the gap and tilt adjustment circuit (i.e., the adjustment circuit) 480 to adjust the gap and relative tilt between the ESC 106 and the showerhead 110. The capacitance measurement circuit 460, the gap measurement circuit 470, and the tilt measurement circuit 472 measure the gap and relative tilt between the ESC 106 and the showerhead 110 as described above with reference to FIGS. 5A-5D, and are therefore not described again for brevity.

Three actuators 850, 852, and 854 are mounted to the showerhead 110 to adjust the gap and relative tilt between the ESC 106 and the showerhead 110 as follows. The actuators 850, 852, and 854 are mounted to the top plate 752 of the processing chamber 102. For example, the actuators 850, 852, and 854 are circumferentially spaced apart from each other by 120°. Each of the actuators 850, 852, and 854 has three angular degrees of freedom. Of the three degrees of freedom, two degrees of freedom are used to adjust the relative tilt, and one degree of freedom is used to adjust the gap between the ESC 106 and the showerhead 110. The actuators 850, 852, and 854 are driven by respective motors 870, 872, and 874. The adjustment circuit 480 adjusts the gap and relative tilt between the ESC 106 and the showerhead 110 by controlling the motors 870, 872, and 874 as follows.

In use, the gap measurement circuit 470 measures the gap between the ESC 106 and the showerhead 110 using any of the systems 650, 700, or 750 depending on the electrode configuration used in the ESC 106, as described above with reference to FIGS. 5A-5D. The tilt measurement circuit 472 measures the relative tilt between the ESC 106 and the showerhead 110 using any of the systems 650, 700, or 750 depending on the electrode configuration used in the ESC 106, as described above with reference to FIGS. 5A-5D.

If no tilt or a specific tilt (magnitude and direction) is desired, any detected tilt may be adjusted as follows to achieve the desired tilt. Based on the measured tilt and the desired tilt, the adjustment circuit 480 adjusts the tilt of the ESC 106 relative to the showerhead 110 (magnitude and direction) as desired (i.e., no tilt or desired tilt) by controlling the motors 870, 872, and 874 that drive the respective actuators 850, 852, and 854. Based on the measured gap and the desired gap, the adjustment circuit 480 controls the gap between the ESC 106 and the showerhead 110 by controlling the motors 870, 872, and 874 that drive the respective actuators 850, 852, and 854.

FIG. 7 shows a method 900 for measuring and adjusting the gap and tilt between the ESC 106 and the showerhead 110. The method 900 can be performed by the controller 160. In the following description, the term control refers to the controller 160. At 902, control moves the ESC 106 comprising three or more electrodes proximate to the showerhead 110. At 904, control selects a first pair of electrodes in the ESC 106. At 906, control measures a first capacitance between the first pair of electrodes and the showerhead 110. At 908, control selects a second pair of electrodes in the ESC 106. At 910, control measures a second capacitance between the second pair of electrodes and the showerhead 110. At 912, control selects a third pair of electrodes in the ESC 106. At 914, control measures a third capacitance between the third pair of electrodes and the showerhead 110. While not shown, additional capacitance measurements can be made when four or more electrodes are used as described above with reference to FIGS. 5B and 5C. Note that alternatively, at 904-914, selecting another circuit (i.e., another electrode pair) could be accomplished using multiplexing, or by simply reading the measurement made if a dedicated measurement circuit such as that shown in FIG. 4D is utilized.

At 920, control measures the distance (i.e., gap) between the ESC 106 and the showerhead 110 based on the capacitance measurements. At 924, control determines whether to adjust the gap. If the gap is to be adjusted, at 926, control moves one or more actuators that are mounted to the ESC 106, the showerhead 110, or both to adjust the gap until a desired gap is achieved. Control determines whether the desired gap is achieved by measuring the capacitances while moving the actuators. Subsequently or if the gap is not be adjusted, control proceeds to 930.

At 930, control measures the relative tilt (magnitude and direction) between the ESC 106 and the showerhead 110 based on the capacitance measurements (e.g., using plane fitting as described above). At 932, control determines whether to adjust the relative tilt (magnitude and/or direction). If the relative tilt (magnitude and/or direction) is to be adjusted, at 934, control moves one or more actuators that are mounted to the ESC 106, the showerhead 110, or both to adjust the relative tilt (magnitude and/or direction) until a desired relative tilt (magnitude and/or direction) is achieved. Control determines whether the desired relative tilt (magnitude and/or direction) is achieved by measuring the capacitances while moving the actuators. Subsequently or if the relative tilt is not be adjusted, control proceeds to 940. At 940, control loads and processes the substrate 108 with the adjusted gap and relative tilt between the ESC 106 and the showerhead 110.

In addition, the systems described above with reference to FIGS. 5A-6C can detect if a substrate is misplaced (i.e., placed off-center) on the ESC 106. If the substrate is misplaced, these systems can determine the direction in which the substrate is off-center, calculate a corrective action, and execute the corrective action as described with reference to FIGS. 8A and 8B below. For example, in FIG. 8A, the substrate may be initially misplaced by a robot that places the substrate on the ESC 106. The system can detect that the substrate is off-center, and the substrate can be centered manually or using the robot. Additionally or alternatively, in FIG. 8B, the substrate may move off-center during processing due to an issue with the clamping system, and/or a degradation in other mechanisms such as backside gas pressure used with the ESC 106. The system can detect that the substrate is off-center, halt the process, initiate a de-clamping sequence, institute a relative motion between the substrate and the ESC 106 to re-center the substrate, re-clamp the substrate, and restart/resume the process.

FIG. 8A shows a method 950 for detecting whether a substrate (e.g., the substrate 108) is misplaced (i.e., placed off-center) on the pedestal. The method 950 can be performed by the controller 160. In the following description, the term control refers to the controller 160. At 952, control places the substrate on the ESC 106 (e.g., using a robot). At 954, control selects a first pair of electrodes in the ESC 106. At 956, control measures a first capacitance between the first pair of electrodes and the substrate. At 958, control selects a second pair of electrodes in the ESC 106. At 960, control measures a second capacitance between the second pair of electrodes and the substrate. At 962, control selects a third pair of electrodes in the ESC 106. At 964, control measures a third capacitance between the third pair of electrodes and the substrate. While not shown, additional capacitance measurements can be made when four or more electrodes are used as described above with reference to FIGS. 5B and 5C. Note that alternatively, at 904-914, selecting another circuit (i.e., another electrode pair) could be accomplished using multiplexing, or by simply reading the measurement made if a dedicated measurement circuit such as that shown in FIG. 4D is utilized.

At 966, control determines based on the capacitance measurements whether the substrate is off-center. For example, control may determine that the substrate is off-center is the three capacitance values are unequal (e.g., one capacitance value is different than the other two capacitance values). The method 950 ends if the substrate is not off-center. If the substrate is off-center, at 968, control determines based on the capacitance values the direction in which the substrate is off-center. At 970, control calculates an adjustment to center the substrate. At 972, the method 950 initiates a relative motion between the substrate and the ESC 106 to center the substrate (e.g., the robot may pick up and replace the substrate on the ESC 106). At 974, control processes the substrate, and the method 950 ends.

FIG. 8B shows a method 1000 for detecting whether a substrate (e.g., the substrate 108) moves off-center on the pedestal during processing. The method 1000 can be performed by the controller 160. In the following description, the term control refers to the controller 160. At 1002, control begins processing the substrate arranged on the ESC 106. At 1004, control selects a first pair of electrodes in the ESC 106. At 1006, control measures a first capacitance between the first pair of electrodes and the substrate. At 1008, control selects a second pair of electrodes in the ESC 106. At 1010, control measures a second capacitance between the second pair of electrodes and the substrate. At 1012, control selects a third pair of electrodes in the ESC 106. At 1014, control measures a third capacitance between the third pair of electrodes and the substrate. While not shown, additional capacitance measurements can be made when four or more electrodes are used as described above with reference to FIGS. 5B and 5C. Note that alternatively, at 904-914, selecting another circuit (i.e., another electrode pair) could be accomplished using multiplexing, or by simply reading the measurement made if a dedicated measurement circuit such as that shown in FIG. 4D is utilized.

At 1016, control determines based on the capacitance measurements whether the substrate is off-center. For example, control may determine that the substrate is off-center is the three capacitance values are unequal (e.g., one capacitance value is different than the other two capacitance values). If the substrate is not off-center, at 1017, control continues processing the substrate, and control returns to 1004.

If the substrate is off-center, at 1018, control determines based on the capacitance values the direction in which the substrate is off-center. At 1020, control calculates an adjustment to center the substrate. At 1022, control halts the process. At 1024, control initiates a de-clamping sequence and de-clamps the substrate. At 1026, the method 950 initiates a relative motion between the substrate and the ESC 106 to center the substrate (e.g., the robot may pick up and replace the substrate on the ESC 106). At 1028, control clamps the substrate. At 1030, control resumes processing the substrate, and the method 1000 ends.

In addition, using the methods described above for measuring the gap and tilt between the pedestal and the showerhead, the systems of FIGS. 5A-6C can also measure substrate-pedestal gap, relative tilt, and tilt axis orientation when the substrate is placed above the pedestal (e.g., on lift pins; see FIG. 10) and relative eccentricity when the substrate is placed on the pedestal. Relative eccentricity is a difference between a center of the substrate and a center of the pedestal. Preferentially, the center of the substrate should be aligned with the center of the pedestal, in which case the relative eccentricity is zero. From a sensing perspective, measuring eccentricity is the same as detecting showerhead-ESC relative tilt, except that the systems measure substrate-ESC relative eccentricity at a very small gap (e.g., with a small lift on lift pins).

Relative eccentricity is becoming increasingly important as manufacturers are pushing die layouts closer to the outer diameter (i.e., edge) of the substrate. If the wafer is not centered, process defects can occur closer to the edge of the substrate. Further, when the substrate is being placed on the pedestal, the substrate is held on the lift pins slightly above the pedestal for a period of time to achieve thermal equilibrium between the pedestal and the substrate (i.e., so that heat gradually transfers from the pedestal to the substrate) before the substrate is clamped to the pedestal. For uniform heat transfer to occur across the substrate and to minimize various defects from occurring in the substrate, the substrate should be preferentially held parallel to the pedestal. To achieve these objectives, the gap and tilt between the pedestal and the substrate are measured when the substrate is placed above the pedestal (e.g., on lift pins), and the relative eccentricity is measured when the substrate is placed on the pedestal. While the lift pins are not adjusted based on the measurements, the measurements can be used to perform adjustments to the lift pins and other mechanisms when the tool or the process module is serviced next. The relative eccentricity measurement is the same as determining whether the substrate is off-center as described above with reference to FIGS. 8A and 8B and is therefore not repeated for brevity.

FIG. 9 shows a method 1050 for measuring the gap and relative tilt between the pedestal (e.g., the ESC 106) and the substrate (e.g., the substrate 108), which is essentially similar to measuring the gap and relative tilt between the pedestal and the showerhead described above with reference to FIG. 7. The method 1050 can be performed by the controller 160. In the following description, the term control refers to the controller 160.

At 1052, prior to clamping and processing the substrate, the substrate is held on lift pins slight above the ESC 106. At 1054, control selects a first pair of electrodes in the ESC 106. At 1056, control measures a first capacitance between the first pair of electrodes and the substrate. At 1058, control selects a second pair of electrodes in the ESC 106. At 1060, control measures a second capacitance between the second pair of electrodes and the substrate. At 1062, control selects a third pair of electrodes in the ESC 106. At 1064, control measures a third capacitance between the third pair of electrodes and the substrate. While not shown, additional capacitance measurements can be made when four or more electrodes are used as described above with reference to FIGS. 5B and 5C. Note that alternatively, at 904-914, selecting another circuit (i.e., another electrode pair) could be accomplished using multiplexing, or by simply reading the measurement made if a dedicated measurement circuit such as that shown in FIG. 4D is utilized.

At 1066, control measures the distance (i.e., gap) between the ESC 106 and the substrate based on the capacitance measurements. At 1068, control measures the relative tilt (magnitude and direction) between the ESC 106 and the substrate based on the capacitance measurements (e.g., using plane fitting as described above). At 1070, control determines whether an adjustment is needed to the relative tilt (magnitude and/or direction) to hold the substrate parallel to the ESC 106 for uniform thermal transfer from the ESC 106 to the substrate while the substrate is held on the lift pins slightly above the ESC 106. If the relative tilt (magnitude and/or direction) needs an adjustment, at 1072, control provides such an indication so that the lift pins can be adjusted during next service. At 1074, control determines if a thermal equilibrium between the ESC 106 and the substrate is reached. Control waits until the thermal equilibrium is reached. Thereafter, at 1076, control clamps the substrate to the ESC 106 and processes the substrate.

FIG. 10 shows an example of lift pins used with a pedestal 1100. For example, the pedestal may be used instead of the ESC 106 in the substrate processing system 100 shown in FIG. 1 and may include any of the electrodes shown in FIGS. 2A-2E. The pedestal 1100 includes a substrate supporting plate 1110, a supporting column 1112, and a base 1114. The substrate supporting plate 1110 may include any of the electrodes shown in FIGS. 2A-2E. The base 1114 may include a ring-shaped platform or structure (also called a lift ring) in which the lift pins and lift pin holder assemblies described below can be installed. In some examples, the supporting column 1112 moves relative to the base 1114.

Lift pin holder assemblies 1120 (shown generically) are arranged below the substrate supporting plate 1110 on the base 1114. The lift pin holder assembly 1120 includes a base portion 1126, a lift pin 1130, and a lift pin holder 1134. In some examples, the lift pin holder assembly 1120 and the lift pin 1130 are generally cylindrically shaped. The lift pin 1130 includes a circular groove 1131, which is useful in locking the lift pin 1130 into the lift pin holder assemblies 1120.

One or more guiding elements 1140 may be used to help guide the lift pin 1130. In some examples, the guiding elements 1140 include a cylindrical support 1143 that is attached to a bottom surface of the substrate supporting plate 1110. The cylindrical support 1143 includes a bore 1145 for receiving a middle portion the lift pin 1130. Likewise, the substrate supporting plate 1110 includes a bore 1141 (shown generically) for receiving an upper portion of the lift pin 1130.

In use, the base 1114 may be raised and lowered relative to the substrate supporting plate 1110 (e.g., using the controller 160 and suitable actuators) to vary a height of the upper end of the lift pins 1130 relative to an upper surface of the substrate supporting plate 1110. As a result, the lift pins 1130 lift the substrate 108 above the substrate supporting plate 1110 or are positioned to receive the substrate 1108 to be loaded onto the substrate supporting plate 1110. A gap 1148 is provided between the substrate 1108 and the upper surface of the substrate supporting plate 1110.

Additionally, various clamping arrangements can be employed using the electrodes shown in FIGS. 2B-2F and using the biasing systems of FIGS. 3B-3D (and variations thereof). In the examples of the clamping arrangements described below, the controller 160 can control the power supply and control circuit 390 and various switches shown in FIGS. 3B-3D (and variations thereof) to supply different potentials to the electrodes as described below.

For example, the electrodes shown in FIGS. 2B-2F may be arranged in a monopolar clamping arrangement where all of the electrodes are connected to the same DC potential. Alternatively, the electrodes shown in FIGS. 2B-2F may be arranged in different bipolar clamping arrangements where designated pairs of electrodes are connected to DC potentials of opposite polarities. Illustrative examples of the clamping arrangements follow.

For example, in FIG. 2B, the inner electrodes 252, 254, 256 may be connected to a first DC potential having a first polarity, and the outer electrode 259 may be connected to a second DC potential having a second polarity that is opposite to the first polarity. For example, in FIG. 2C, the inner electrode 302 may be connected to a first DC potential having a first polarity, and the outer electrodes 252, 254, 256 may be connected to a second DC potential having a second polarity that is opposite to the first polarity. For example, in FIG. 2E, the inner electrodes 252, 254, 256 may be connected to a first DC potential having a first polarity, and the outer electrodes 352, 354, 356 may be connected to a second DC potential having a second polarity that is opposite to the first polarity.

Many other alternate clamping arrangements are possible. For example, in an “AC” clamping arrangement, the outer electrode (or in FIGS. 2C and 2D, the inner electrode 302) may be connected to a first potential and all other electrodes may be connected to a second time-varying potential whose magnitude reaches a peak with a phase shift from each other, where the phase shift is approximately equal to 360 degrees divided by the number of the other electrodes. FIG. 11A shows a timing diagram of the potentials in this example.

Alternatively, suppose there are four (or more) even number of inner electrodes (e.g., see FIG. 2F) that are enumerated by going around the pedestal (e.g., in FIG. 2F, the electrodes 312, 314, 316, and 318 numbered as electrodes E1, E2, E3, E4, respectively). In a bipolar arrangement, the first electrode E1 312 and the third electrode E3 316 diametrically opposite to the first electrode E1 312 may form a first electrode pair and may be connected to a first potential having a first polarity, and the second electrode E2 314 and the fourth electrode E4 318 diametrically opposite to the second electrode E2 314 may for a second electrode pair and may be connected to a second potential having a second polarity that is opposite to the first polarity.

Alternatively, in an “AC” clamping arrangement, the first electrode E1 312 and the third electrode E3 316 diametrically opposite to the first electrode E1 312 may form a first electrode pair. The first electrode E1 312 may be connected to a first potential having a first polarity, and the third electrode E3 316 may be connected to a second potential having a second polarity that is opposite to the first polarity. The second electrode E2 314 and the fourth electrode E4 318 diametrically opposite to the second electrode E2 314 may form a second electrode pair. The second electrode E2 314 may be connected to the first potential having the first polarity with a phase shift of 90 degrees (i.e., 360 degrees divided by the number of electrodes, which is four in this example) from the first electrode E1 312, and the fourth electrode E4 318 may be connected to the second potential having the second polarity with a phase shift of 90 degrees from the third electrode E3 316. FIG. 11B shows a timing diagram of the potentials in this example.

In general, if there are even number of inner electrodes that are enumerated by going around the pedestal, then a first electrode pair may be formed by a first electrode and a second electrode that is diametrically opposite to the first electrode. Starting from the first electrode and going around the pedestal, additional unpaired electrodes are paired similar to the first and second electrodes. In the first electrode pair including the first and second electrodes, the first electrode may be connected to a first time-varying potential and the second electrode diametrically opposite to the first electrode may be connected to a second time-varying potential having an opposite polarity to the first time-varying potential. The electrodes in each successive electrode pair of diametrically opposite electrodes are connected to the first and second time-varying potentials similar to the first and second electrodes in the first electrode pair with each successive electrode pair having a phase shift from the first electrode pair that is equal to 360 degrees divided by the number of electrodes.

Further, the size and shape of the electrodes need not be balanced or symmetric. The sensitivity of the system is enhanced the larger the area of the electrodes as well as the closer the electrodes are to the wafer.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another are within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A system comprising:
a pedestal arranged below a showerhead in a processing chamber and including at least three electrodes to clamp a substrate to the pedestal during processing; and
a controller configured to measure a pedestal-to-showerhead gap and at least one of a magnitude and a direction of a relative tilt between the pedestal and the showerhead by sensing impedances between the at least three electrodes and the showerhead.

2. The system of claim 1 wherein the pedestal further comprises a circumferential electrode surrounding the at least three electrodes.

3. The system of claim 1 wherein the pedestal comprises a dielectric plate and wherein the at least three electrodes are arranged in the dielectric plate.

4. The system of claim 3 wherein the dielectric plate is laminated.

5. The system of claim 3 wherein the dielectric plate is monolithic.

6. The system of claim 3 wherein the dielectric plate is made of a single crystalline material, a vitreous material, or a polymeric material.

7. The system of claim 1 further comprising:
a plurality of actuators configured to at least one of move the pedestal and reorient the relative tilt between the pedestal and the showerhead,
wherein each of the plurality of actuators has at least three degrees of freedom.

8. The system of claim 7 wherein the plurality of actuators is configured to at least one of move the pedestal and reorient the relative tilt between the pedestal and the showerhead by moving the pedestal, moving the showerhead, or influencing a relative positioning of the pedestal and the showerhead.

9. The system of claim 7 wherein the controller is configured to control the actuators to adjust the pedestal-to-showerhead gap and to adjust the at least one of the magnitude and the direction of the relative tilt.

10. The system of claim 1 wherein the controller is configured to determine based on the impedances whether the substrate is absent, present but not clamped to the pedestal, or present and clamped to the pedestal.

11. The system of claim 1 wherein the controller is configured to measure a pedestal-to-substrate gap and at least one of a magnitude and a direction of a relative tilt between the pedestal and the substrate by sensing the impedances between the at least three electrodes and the substrate.

12. The system of claim 1 wherein the controller is configured to measure pedestal-to-substrate relative eccentricity by sensing the impedances between the at least three electrodes and the substrate.

13. The system of claim 1 wherein the pedestal and the showerhead are arranged along a vertical axis and wherein the at least three electrodes are arranged in the pedestal in one or more planes parallel to a horizontal plane that is perpendicular to the vertical axis.

14. The system of claim 1 wherein the at least three electrodes are pie-shaped, the system further comprising an annular electrode having a greater radius than the at least three electrodes.

15. The system of claim 14 wherein the annular electrode includes a plurality of spoke-like portions extending radially inwards and wherein each of the spoke-like portions is arranged between a different pair of electrodes from the at least three electrodes.

16. The system of claim 14 wherein the pedestal and the showerhead are arranged along a vertical axis and wherein the at least three electrodes and the annular electrode are arranged in the pedestal in one or more planes parallel to a horizontal plane that is perpendicular to the vertical axis.

17. The system of claim 1 wherein the at least three electrodes are pie-shaped, the system further comprising a disc shaped electrode having a smaller radius than the at least three electrodes.

18. The system of claim 17 wherein the pedestal and the showerhead are arranged along a vertical axis and wherein the at least three electrodes are arranged in the pedestal in one or more planes parallel to a horizontal plane that is perpendicular to the vertical axis and wherein the disc shaped electrode is arranged in the pedestal in a separate plate parallel to the horizontal plane.

19. The system of claim 1 wherein the at least three electrodes are pie-shaped, the system further comprising a plurality of arc-shaped electrodes having a radius greater than the at least three electrodes and arranged around the at least three electrodes.

20. The system of claim 19 wherein the at least three electrodes and the plurality of arc-shaped electrodes are arranged in the pedestal in one or more planes parallel to a horizontal plane.

21. The system of claim 1 further comprising a plurality of switches wherein the controller is configured to connect to the at least three electrodes in pairs using the plurality of switches.

22. The system of claim 1 wherein the controller comprises a plurality of sensing circuits connected directly to respective pairs of the at least three electrodes to sense impedances.

23. The system of claim 1 further comprising:
an annular electrode having a greater radius than the at least three electrodes; and
a plurality of switches,
wherein the controller is configured to connect to the at least three electrodes and the annular electrode in pairs using the plurality of switches, with each of the pairs including the annular electrode and a different one of the at least three electrodes.

24. The system of claim 17 further comprising a plurality of switches wherein the controller is configured to connect to the at least three electrodes and the disc shaped electrode in pairs using the plurality of switches, with each of the pairs including the disc shaped electrode and a different one of the at least three electrodes.

25. The system of claim 19 further comprising a plurality of switches wherein the controller is configured to connect to the at least three electrodes and the plurality of arc-shaped electrodes in pairs using the plurality of switches, with each of the pairs including a different one of the at least three electrodes and a different one of the plurality of arc-shaped electrodes.

26. The system of claim 1 wherein the pedestal comprises:
a baseplate; and
a dielectric plate arranged on the baseplate,
wherein the at least three electrodes are arranged in the dielectric plate.

27. The system of claim 1 wherein the at least three electrodes are connected to a single DC potential.

28. The system of claim 2 wherein:
the at least three electrodes are connected to a first DC potential having a first polarity; and
the circumferential electrode is connected to a second DC potential having a second polarity that is opposite to the first polarity.

29. The system of claim 17 wherein:
the at least three electrodes are connected to a first DC potential having a first polarity; and
the disc shaped electrode is connected to a second DC potential having a second polarity that is opposite to the first polarity.

30. The system of claim 19 wherein:
the at least three electrodes are connected to a first DC potential having a first polarity; and
the plurality of arc-shaped electrodes is connected to a second DC potential having a second polarity that is opposite to the first polarity.

31. The system of claim 16 wherein:
the disc shaped electrode is connected to a first potential; and
the at least three electrodes are connected to a time-varying potential with a phase shift of 360 degrees divided a total number of the at least three electrodes.

32. The system of claim 1 wherein the at least three electrodes include:
a first pair of electrodes arranged diametrically opposite to each other and connected to a first DC potential having a first polarity; and
a second pair of electrodes arranged diametrically opposite to each other and connected to a second DC potential having a second polarity that is opposite to the first polarity.

33. The system of claim 1 wherein the at least three electrodes include:
a first pair of electrodes including a first electrode and a second electrode that are arranged diametrically opposite to each other and that are respectively connected to first time-varying potentials having a first polarity and a second polarity that is opposite to the first polarity; and
a second pair of electrodes including a third electrode and a fourth electrode that are arranged diametrically opposite to each other and that are respectively connected to second time-varying potentials having the first polarity and the second polarity,
wherein the second time-varying potentials have a phase shift of 360 degrees divided a total number of the at least three electrodes.

34. The system of claim 1 wherein the controller is configured to measure the pedestal-to-showerhead gap and at least one of the magnitude and the direction of the relative tilt between the pedestal and the showerhead by sensing impedances between the at least three electrodes and the showerhead with plasma present between the pedestal and the showerhead.

35. A system comprising:
a pedestal arranged below a showerhead in a processing chamber and including:
at least three electrodes to clamp a substrate to the pedestal during processing, wherein the at least three electrodes are pie-shaped; and
an annular electrode having a greater radius than the at least three electrodes; and
a controller configured to measure a pedestal-to-showerhead gap and at least one of a magnitude and a direction of a relative tilt between the pedestal and the showerhead by sensing impedances between the showerhead and the at least three electrodes and the annular electrode.

36. The system of claim 35 wherein the annular electrode includes a plurality of spoke-like portions extending radially inwards and wherein each of the spoke-like portions is arranged between a different pair of electrodes from the at least three electrodes.

37. The system of claim 35 wherein the pedestal and the showerhead are arranged along a vertical axis and wherein the at least three electrodes and the annular electrode are arranged in the pedestal in one or more planes parallel to a horizontal plane that is perpendicular to the vertical axis.

38. The system of claim 35 further comprising a plurality of switches wherein the controller is configured to connect to the at least three electrodes and the annular electrode in pairs using the plurality of switches, with each of the pairs including the annular electrode and a different one of the at least three electrodes.

39. The system of claim 35 further comprising:
a plurality of actuators configured to at least one of move the pedestal and reorient the relative tilt between the pedestal and the showerhead,
wherein each of the plurality of actuators has at least three degrees of freedom.

40. The system of claim 39 wherein the plurality of actuators is configured to at least one of move the pedestal and reorient the relative tilt between the pedestal and the showerhead by moving the pedestal, moving the showerhead, or influencing a relative positioning of the pedestal and the showerhead.

41. The system of claim 39 wherein the controller is configured to control the actuators to adjust the pedestal-to-showerhead gap and to adjust the at least one of the magnitude and the direction of the relative tilt.

42. The system of claim 35 wherein the controller is configured to determine based on the impedances whether the substrate is absent, present but not clamped to the pedestal, or present and clamped to the pedestal.

43. The system of claim 35 wherein the controller is configured to measure a pedestal-to-substrate gap and at least one of a magnitude and a direction of a relative tilt between the pedestal and the substrate by sensing the impedances between the substrate and the at least three electrodes and the annular electrode.

44. The system of claim 35 wherein the controller is configured to measure pedestal-to-substrate relative eccentricity by sensing the impedances between the substrate and the at least three electrodes and the annular electrode.

45. The system of claim 35 wherein the controller comprises a plurality of sensing circuits connected directly to respective pairs of the at least three electrodes and the annular electrode to sense impedances.

46. The system of claim 35 wherein the pedestal comprises:
a baseplate; and
a dielectric plate arranged on the baseplate,
wherein the at least three electrodes and the annular electrode are arranged in the dielectric plate.

47. The system of claim 35 wherein the at least three electrodes and the annular electrode are connected to a single DC potential.

48. The system of claim 35 wherein:
the at least three electrodes are connected to a first DC potential having a first polarity; and
the annular electrode is connected to a second DC potential having a second polarity that is opposite to the first polarity.

49. The system of claim 35 wherein the at least three electrodes include:
a first pair of electrodes arranged diametrically opposite to each other and connected to a first DC potential having a first polarity; and
a second pair of electrodes arranged diametrically opposite to each other and connected to a second DC potential having a second polarity that is opposite to the first polarity.

50. The system of claim 35 wherein the at least three electrodes include:
a first pair of electrodes including a first electrode and a second electrode that are arranged diametrically opposite to each other and that are respectively connected to first time-varying potentials having a first polarity and a second polarity that is opposite to the first polarity; and
a second pair of electrodes including a third electrode and a fourth electrode that are arranged diametrically opposite to each other and that are respectively connected to second time-varying potentials having the first polarity and the second polarity,
wherein the second time-varying potentials have a phase shift of 360 degrees divided a total number of the at least three electrodes.

51. The system of claim 35 wherein the controller is configured to measure the pedestal-to-showerhead gap and at least one of the magnitude and the direction of the relative tilt between the pedestal and the showerhead by sensing impedances between the showerhead and the at least three electrodes and the annular electrode with plasma present between the pedestal and the showerhead.

52. A system comprising:
a pedestal arranged below a showerhead in a processing chamber and including:
at least three electrodes to clamp a substrate to the pedestal during processing, wherein the at least three electrodes are pie-shaped; and
a disc shaped electrode having a smaller radius than the at least three electrodes; and
a controller configured to measure a pedestal-to-showerhead gap and at least one of a magnitude and a direction of a relative tilt between the pedestal and the showerhead by sensing impedances between the showerhead and the at least three electrodes and the disc shaped electrode.

53. The system of claim 52 wherein the pedestal and the showerhead are arranged along a vertical axis and wherein the at least three electrodes are arranged in the pedestal in one or more planes parallel to a horizontal plane that is perpendicular to the vertical axis and wherein the disc shaped electrode is arranged in the pedestal in a separate plate parallel to the horizontal plane.

54. The system of claim 52 further comprising a plurality of switches wherein the controller is configured to connect to the at least three electrodes and the disc shaped electrode in pairs using the plurality of switches, with each of the pairs including the disc shaped electrode and a different one of the at least three electrodes.

55. The system of claim 52 wherein:
the at least three electrodes are connected to a first DC potential having a first polarity; and
the disc shaped electrode is connected to a second DC potential having a second polarity that is opposite to the first polarity.

56. The system of claim 52 further comprising:
a plurality of actuators configured to at least one of move the pedestal and reorient the relative tilt between the pedestal and the showerhead,
wherein each of the plurality of actuators has at least three degrees of freedom.

57. The system of claim 56 wherein the plurality of actuators is configured to at least one of move the pedestal and reorient the relative tilt between the pedestal and the showerhead by moving the pedestal, moving the showerhead, or influencing a relative positioning of the pedestal and the showerhead.

58. The system of claim 56 wherein the controller is configured to control the actuators to adjust the pedestal-to-showerhead gap and to adjust the at least one of the magnitude and the direction of the relative tilt.

59. The system of claim 52 wherein the controller is configured to determine based on the impedances whether the substrate is absent, present but not clamped to the pedestal, or present and clamped to the pedestal.

60. The system of claim 52 wherein the controller is configured to measure a pedestal-to-substrate gap and at least one of a magnitude and a direction of a relative tilt between the pedestal and the substrate by sensing the impedances between the substrate and the at least three electrodes and the disc shaped electrode.

61. The system of claim 52 wherein the controller is configured to measure pedestal-to-substrate relative eccentricity by sensing the impedances between the substrate and the at least three electrodes and the disc shaped electrode.

62. The system of claim 52 wherein the controller comprises a plurality of sensing circuits connected directly to respective pairs of the at least three electrodes and the disc shaped electrode to sense impedances.

63. The system of claim 52 wherein the pedestal comprises:
a baseplate; and
a dielectric plate arranged on the baseplate,
wherein the at least three electrodes and the disc shaped electrode are arranged in the dielectric plate.

64. The system of claim 52 wherein the at least three electrodes and the disc shaped electrode are connected to a single DC potential.

65. The system of claim 52 wherein the at least three electrodes include:
a first pair of electrodes arranged diametrically opposite to each other and connected to a first DC potential having a first polarity; and
a second pair of electrodes arranged diametrically opposite to each other and connected to a second DC potential having a second polarity that is opposite to the first polarity.

66. The system of claim 52 wherein the at least three electrodes include:
a first pair of electrodes including a first electrode and a second electrode that are arranged diametrically opposite to each other and that are respectively connected to first time-varying potentials having a first polarity and a second polarity that is opposite to the first polarity; and
a second pair of electrodes including a third electrode and a fourth electrode that are arranged diametrically opposite to each other and that are respectively connected to second time-varying potentials having the first polarity and the second polarity,
wherein the second time-varying potentials have a phase shift of 360 degrees divided a total number of the at least three electrodes.

67. The system of claim 52 wherein the controller is configured to measure the pedestal-to-showerhead gap and at least one of the magnitude and the direction of the relative tilt between the pedestal and the showerhead by sensing impedances between the showerhead and the at least three electrodes and the disc shaped electrode with plasma present between the pedestal and the showerhead.

68. A system of comprising:
a pedestal arranged below a showerhead in a processing chamber and including:
at least three electrodes to clamp a substrate to the pedestal during processing, wherein the at least three electrodes are pie-shaped; and
a plurality of arc-shaped electrodes having a radius greater than the at least three electrodes and arranged around the at least three electrodes; and
a controller configured to measure a pedestal-to-showerhead gap and at least one of a magnitude and a direction of a relative tilt between the pedestal and the showerhead by sensing impedances between the showerhead and the at least three electrodes and the plurality of arc-shaped electrodes.

69. The system of claim 68 wherein the pedestal and the showerhead are arranged along a vertical axis and wherein the at least three electrodes and the plurality of arc-shaped electrodes are arranged in the pedestal in one or more planes parallel to a horizontal plane that is perpendicular to the vertical axis.

70. The system of claim 68 further comprising a plurality of switches wherein the controller is configured to connect to the at least three electrodes and the plurality of arc-shaped electrodes in pairs using the plurality of switches, with each of the pairs including a different one of the at least three electrodes and a different one of the plurality of arc-shaped electrodes.

71. The system of claim 68 wherein:
the at least three electrodes are connected to a first DC potential having a first polarity; and
the plurality of arc-shaped electrodes is connected to a second DC potential having a second polarity that is opposite to the first polarity.

72. The system of claim 68 further comprising:
a plurality of actuators configured to at least one of move the pedestal and reorient the relative tilt between the pedestal and the showerhead,
wherein each of the plurality of actuators has at least three degrees of freedom.

73. The system of claim 72 wherein the plurality of actuators is configured to at least one of move the pedestal and reorient the relative tilt between the pedestal and the showerhead by moving the pedestal, moving the showerhead, or influencing a relative positioning of the pedestal and the showerhead.

74. The system of claim 72 wherein the controller is configured to control the actuators to adjust the pedestal-to-showerhead gap and to adjust the at least one of the magnitude and the direction of the relative tilt.

75. The system of claim 68 wherein the controller is configured to determine based on the impedances whether the substrate is absent, present but not clamped to the pedestal, or present and clamped to the pedestal.

76. The system of claim 68 wherein the controller is configured to measure a pedestal-to-substrate gap and at least one of a magnitude and a direction of a relative tilt between the pedestal and the substrate by sensing the impedances between the substrate and the at least three electrodes and the plurality of arc-shaped electrodes.

77. The system of claim 68 wherein the controller is configured to measure pedestal-to-substrate relative eccentricity by sensing the impedances between the substrate and the at least three electrodes and the plurality of arc-shaped electrodes.

78. The system of claim 68 wherein the controller comprises a plurality of sensing circuits connected directly to respective pairs of the at least three electrodes and the plurality of arc-shaped electrodes to sense impedances.

79. The system of claim 68 wherein the pedestal comprises:
a baseplate; and
a dielectric plate arranged on the baseplate,
wherein the at least three electrodes and the plurality of arc-shaped electrodes are arranged in the dielectric plate.

80. The system of claim 68 wherein the at least three electrodes and the plurality of arc-shaped electrodes are connected to a single DC potential.

81. The system of claim 68 wherein the at least three electrodes include:
a first pair of electrodes arranged diametrically opposite to each other and connected to a first DC potential having a first polarity; and
a second pair of electrodes arranged diametrically opposite to each other and connected to a second DC potential having a second polarity that is opposite to the first polarity.

82. The system of claim 68 wherein the at least three electrodes include:
a first pair of electrodes including a first electrode and a second electrode that are arranged diametrically opposite to each other and that are respectively connected to first time-varying potentials having a first polarity and a second polarity that is opposite to the first polarity; and
a second pair of electrodes including a third electrode and a fourth electrode that are arranged diametrically opposite to each other and that are respectively connected to second time-varying potentials having the first polarity and the second polarity,
wherein the second time-varying potentials have a phase shift of 360 degrees divided a total number of the at least three electrodes.

83. The system of claim 68 wherein the controller is configured to measure the pedestal-to-showerhead gap and at least one of the magnitude and the direction of the relative tilt between the pedestal and the showerhead by sensing impedances between the showerhead and the at least three electrodes and the plurality of arc-shaped electrodes with plasma present between the pedestal and the showerhead.
